(19) United States
(12) Patent Application Publication
(10) Pub. No.: US 2025/0080027 A1
(43) Pub. Date: Mar. 6, 2025

(54) MOTOR DRIVE CONTROL DEVICE AND METHOD FOR DETECTING IDLING OF MOTOR

(71) Applicant: MINEBEA MITSUMI Inc., Kitasaku-gun (JP)

(72) Inventor: Hidetoshi HIJIKATA, Kitasaku-gun (JP)

(21) Appl. No.: 18/814,891

(22) Filed: Aug. 26, 2024

(30) Foreign Application Priority Data
Aug. 29, 2023 (JP) 2023-139050

(51) Int. Cl. H02P 27/08; G01R 25/00; G01R 31/34; H02P 23/14

(52) U.S. Cl. CPC H02P 27/08; G01R 25/005; G01R 31/343; H02P 23/14

(57) ABSTRACT

A motor drive control device includes: a control circuit configured to generate a drive control signal; a drive circuit including an inverter circuit including a switch provided corresponding to each phase of coil of the motor, the drive circuit being configured to rotate a rotor of the motor by alternately turning the switch on and off in response to the drive control signal; and a phase voltage detection circuit configured to detect a phase voltage generated between the inverter circuit and each phase of coil of the motor. The control circuit generates an idling control signal and switches a switch state of the inverter circuit to generate a current circulating between each phase of coil of the motor and the inverter circuit when the rotor of the motor is idling, and then determines idling of the motor based on a phase voltage generated at the phase voltage detection circuit by an inductive kickback generated when a path of the current is blocked.

### CROSS-REFERENCE TO RELATED APPLICATIONS

This application claims the benefit of priority to Japanese Patent Application Number 2023-139050 filed on Aug. 29, 2023. The entire contents of the above-identified application are hereby incorporated by reference.

### TECHNICAL FIELD

The present invention relates to a motor drive control device and a method for detecting idling of a motor.

### BACKGROUND ART

Generally, in a motor (hereinafter also referred to as “fan motor”) used for a fan for cooling the inside of an electronic device such as a server, even though the motor is not driven by a drive circuit for driving the motor, the motor may be in a state of rotation, so-called idling, due to inertia or the action of an external force.

Patent Document 1 describes a method for detecting the idling state of the rotor of the motor. This method, upon energizing predetermined switching elements among a plurality of switching elements constituting an inverter circuit of a motor, allows to detect a rotation speed of the fan of the outdoor unit in the idling state due to external force even when an air conditioner is stopped, by extracting a rotation speed of the motor based on currents flowing at the current detection resistors.

### CITATION LIST

### Patent Literature

Patent Document 1: JP 2018-170928 A

### SUMMARY OF INVENTION

### Technical Problem

However, although the method described in Patent Document 1 detects the rotation speed of the motor in the idling state, it may be only required to detect whether the motor is idling in a short time without detecting the rotation speed of the idling motor. For example, when the rotor of the motor is idling, an induced electromotive force is generated, and then when the motor coil and the inverter circuit do not form a closed circuit, an induced voltage is periodically generated at the motor coil (winding), and when the motor coil and the inverter circuit form a closed circuit, an induced current is periodically generated at the motor coil. At this time, the winding resistance measurement and the initial position detection of the rotor using the current flowing at the shunt resistor by energizing the coils of the motor are adversely affected by the periodic change of the induced voltage and the induced current, so that it is necessary to perform the measurement when the motor is not idling. Thus, whether the motor is idling can be used as a determination index for executing various processes.

Whether the motor is idling can be easily detected by using a position sensor, but when detecting whether the motor is idling is possible without using the position sensor, it is preferable from the viewpoint of simplifying the device configuration.

In addition, when the idling state of the motor is detected by using the phase voltage, in the conventional method, all the switching elements constituting the inverter circuit are turned off, so that the idling state of the rotor can be detected by using the zero-cross of the differential voltage between the induced voltage generated in each winding by the rotation of the rotor and the neutral point voltage obtained by synthesizing the voltages of all the windings in the same way as the motor is driven. However, in the case of low speed, the induced voltage generated is small and the detection time of the zero-cross is long, thereby the detectable minimum rotation speed is limited, and consequently, the idling of the motor cannot be determined stably in a short time.

Thus, a motor drive control device capable of stably detecting whether the motor is idling in a short time with a simple configuration without using a position sensor, is desired.

To solve the above problem, it is an object of the present invention to provide a motor drive control device capable of stably detecting whether the motor is idling in a short time without using a position sensor.

### Solution to Problem

A motor drive control device according to an exemplary embodiment of the present invention includes:
a control circuit configured to generate a drive control signal for driving a motor including at least one phase of coil;
a drive circuit including an inverter circuit including a high side switch and a low side switch, the high side switch and the low side switch being provided corresponding to each phase of coil of the motor and connected in series with each other, the drive circuit being configured to rotate the rotor of the motor by alternately turning the high side switch and the low side switch on and off in response to the drive control signal to switch an energization direction of the corresponding phase of coil; and
a phase voltage detection circuit configured to detect a phase voltage generated between the inverter circuit and the corresponding phase of coil of the motor.

The control circuit generates an idling control signal instead of the drive control signal and switches a switch state of the inverter circuit to generate an induced current circulating between each coil of the motor and the inverter circuit when the rotor of the motor is idling, and then determines idling of the motor based on a phase voltage generated at the phase voltage detection circuit by an inductive kickback generated at the inverter circuit when a path of the induced current is blocked.

### Advantageous Effects of Invention

One aspect of the present invention enables a motor drive control device to stably detect whether a motor is idling in a short time without using a position sensor.

### BRIEF DESCRIPTION OF DRAWINGS

FIG. 1 is a diagram illustrating a configuration of a motor unit 100 provided with a motor drive control device 10 according to an embodiment.

FIG. 2 is a diagram for describing a switch state corresponding to a free mode switched by an idling control signal Id.

FIG. 3 is a diagram for describing a switch state corresponding to a charge mode switched by the idling control signal Id.

FIG. 4 is a diagram for describing a switch state corresponding to a discharge mode switched by the idling control signal Id.

FIG. 5 is a diagram illustrating a function block configuration of a control circuit 1 at the motor drive control device 10 according to an embodiment.

FIG. 6 is a diagram illustrating an example of a configuration of a differential voltage detection circuit 15.

FIG. 7 is a diagram illustrating an example of a configuration of a voltage determination unit 16.

FIG. 8 is a diagram illustrating an example of a configuration of a voltage measurement unit 17.

FIG. 9 is a diagram illustrating a timing chart illustrating an example of a signal waveform until a speed command signal Sc is input and the idling determination is completed, after the power is turned on to the motor unit 100.

FIG. 10 is a first pattern of a waveform illustrating a pattern of phase voltage generated at a phase voltage detection circuit in the discharge mode when the rotor of a motor 3 is idling, and a resulting pattern of differential voltage.

FIG. 11 is a second pattern of a waveform illustrating a pattern of phase voltage generated at the phase voltage detection circuit in the discharge mode when the rotor of the motor 3 is idling, and a resulting pattern of differential voltage.

FIG. 12 is a third pattern of a waveform illustrating a pattern of phase voltage generated at the phase voltage detection circuit in the discharge mode when the rotor of the motor 3 is idling, and a resulting pattern of differential voltage.

FIG. 13 is a fourth pattern of a waveform illustrating a pattern of phase voltage generated at the phase voltage detection circuit in the discharge mode when the rotor of the motor 3 is idling, and a resulting pattern of differential voltage.

FIG. 14 is a fifth pattern of a waveform illustrating a pattern of phase voltage generated at the phase voltage detection circuit in the discharge mode when the rotor of the motor 3 is idling, and a resulting pattern of differential voltage.

FIG. 15 is a sixth pattern of a waveform illustrating a pattern of phase voltage generated at the phase voltage detection circuit in the discharge mode when the rotor of motor 3 is idling, and a resulting pattern of differential voltage.

FIG. 16 is a flowchart illustrating an example of the process flow at the time of power-on at the control circuit 1 of the motor drive control device 10 according to an embodiment.

FIG. 17 is a flowchart illustrating an example of the flow of measurement selection by a measurement type selection signal Ss and a measurement phase selection signal Sm output from a state control unit 12.

FIG. 18 is a flowchart illustrating an example of a flow of ADC offset measurement by the control circuit 1 of the motor drive control device 10.

FIG. 19 is a flowchart illustrating an example of a flow of idling detection by the control circuit 1 of the motor drive control device 10.

### DESCRIPTION OF EMBODIMENTS

### 1. Overview of Embodiments

First, a typical embodiment of the invention disclosed herein will be outlined. In the following description, reference sign on the drawings corresponding to the components of the invention are indicated in parentheses as an example.

[1] A motor drive control device (10) according to an exemplary embodiment of the present invention, includes:
a control circuit (1) configured to generate a drive control signal (Sd) for driving a motor including at least one phase of coil;
a drive circuit (2) including an inverter circuit (2a) including a high side switch (Q1, Q3, Q5) and a low side switch (Q2, Q4, Q6), the high side switch and the low side switch being provided corresponding to each phase of coil of the motor (3) and connected in series with each other, the drive circuit being configured to rotate the rotor of the motor by alternately turning the high side switch and the low side switch on and off in response to the drive control signal to switch an energization direction of the corresponding phase of coil; and
a phase voltage detection circuit configured to detect a phase voltage generated between the inverter circuit and the corresponding phase of coil of the motor.

The control circuit generates an idling control signal (Id) instead of the drive control signal and switches a switch state of the inverter circuit to generate an induced current circulating between each phase of coil of the motor and the inverter circuit when the rotor of the motor is idling, and then determines idling of the motor based on a phase voltage generated at the phase voltage detection circuit by an inductive kickback generated at the inverter circuit when a path of the induced current is blocked.

[2] At the motor drive control device according to above [1], the control circuit may include: a first switching unit (21a) configured to switch from a first switch state with all of the high side switches and the low side switches included in the inverter circuit turned off to a second switch state with all of either the high side switches or the low side switches included in the inverter circuit turned on; a second switching unit (21b) configured to switch from the second switch state to the first switch state; and an idling determination unit (22) configured to determine idling of the motor based on the phase voltage generated at the phase voltage detection circuit when switching from the second switch state to the first switch state.

[3] At the motor drive control device according to above [2], the control circuit may include a differential voltage detection circuit configured to detect as a differential voltage detection signal a differential voltage between the phase voltage of one selected phase at the phase voltage detection circuit and a neutral point voltage obtained by synthesizing the phase voltages of all phases at the phase voltage detection circuit, and the idling determination unit may determine idling of the motor based on the differential voltage detection signal.

[4] At the motor drive control device according to above [3], the idling determination unit may set the differential voltage detection signal detected at the differential voltage detection circuit in the second switch state to a reference voltage.

[5] At the motor drive control device according to above [4], when the switch state is switched from the second switch state to the first switch state, the differential voltage detection signal detected at the differential voltage detection circuit for a plurality of times may be used as a measured voltage to calculate a maximum fluctuation voltage difference with the difference between the reference voltage and the measured voltage being maximum, and then when the calculated maximum fluctuation voltage difference is larger than a threshold value, the motor may be determined to be idle.

[6] A method for detecting idling of a motor according to an exemplary embodiment of the present invention is executed at a motor drive control device, and the motor drive control device includes:
a control circuit configured to generate a drive control signal for driving a motor including at least one phase of coil;
a drive circuit including an inverter circuit including a high side switch and a low side switch, the high side switch and the low side switch being provided corresponding to the coil of each phase of the motor and connected in series with each other, the drive circuit being configured to rotate a rotor of the motor by alternately turning the high side switch and the low side switch on and off in response to the drive control signal to switch an energization direction of the coil of the corresponding phase; and
a phase voltage detection circuit configured to detect a phase voltage generated between the inverter circuit and each coil of the corresponding phase of the motor. The method includes:
a first step of switching from a first switch state with all of the high side switches and the low side switches included in the inverter circuit turned off to a second switch state with all of either the high side switches or the low side switches included in the inverter circuit turned on;
a second step of switching from the second switch state to the first switch state; and
a third step of determining idling of the motor based on the phase voltage when switching to the first switch state.

### 2. Specific Examples of Embodiments

Hereinafter, specific examples of embodiments of the present invention will be described with reference to the drawings. In the following description, the same reference signs will be used for the common components in each embodiment, and repeated explanations will be omitted.

### Embodiments

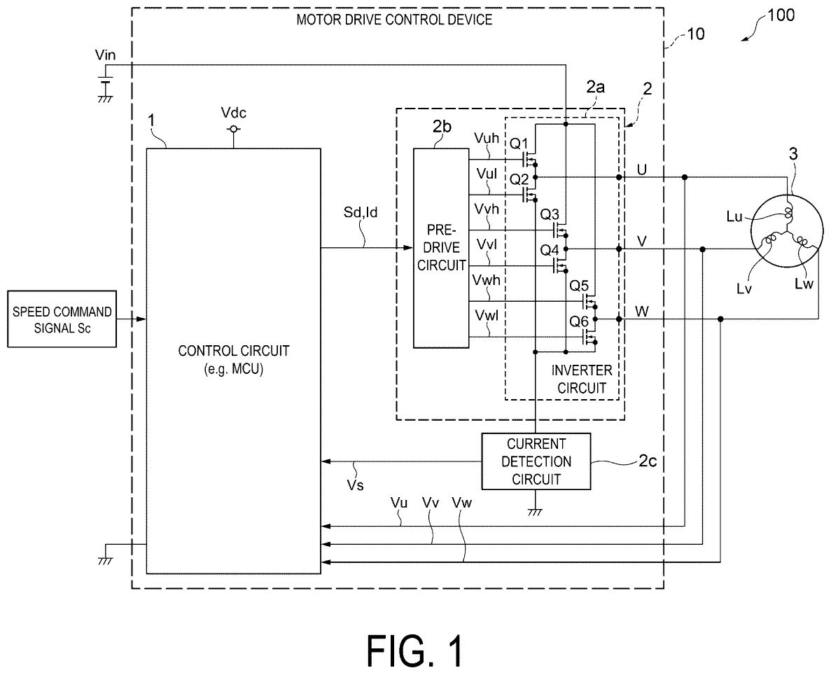

FIG. 1 is a diagram illustrating a configuration of the motor unit 100 provided with the motor drive control device 10 according to an embodiment.

As illustrated in FIG. 1, the motor unit 100 includes the motor 3 and the motor drive control device 10 for controlling the rotation of the motor 3. The motor unit 100 can be applied to various devices using the motor as a driving source, such as a fan or a drone (unmanned aircraft).

The motor 3 is, for example, a permanent magnet synchronous motor (PMSM). In the present embodiment, the motor 3 is, for example, a surface permanent magnet synchronous motor (SPMSM) having three-phase coils (winding) Lu, Lv, Lw. The coils Lu, Lv, and Lw are Y (star)-connected to each other, for example. At this time, the coils may be Δ (delta)-connected to each other.

The motor drive control device 10, for example, applies a 120 degree energized square wave drive signal to the motor 3, thereby periodically passing a drive current to the three-phase coils Lu, Lv, and Lw of the motor 3 to rotate the rotor of the motor 3.

The motor drive control device 10 includes the control circuit 1, a drive circuit 2, and a current detection circuit 2c.

The components of the motor drive control device 10 illustrated in FIG. 1 are a part of the whole, and the motor drive control device 10 may include other components in addition to the components illustrated in FIG. 1.

The drive circuit 2 drives the motor 3 based on a drive control signal Sd output from the control circuit 1 described below. The drive circuit 2 includes, for example, an inverter circuit 2a and a pre-drive circuit 2b. The current detection circuit 2c is provided between the inverter circuit 2a of the drive circuit 2 and the ground.

The inverter circuit 2a is arranged between a DC power supply Vin and the ground potential, and drives the coils Lu, Lv, and Lw of the motor 3 as a load based on the input drive control signal Sd. Specifically, in an embodiment, the inverter circuit 2a includes three switching legs each including two drive transistors connected in series, and drives the motor 3 as a load based on the input drive control signal Sd by alternately turning the respective two drive transistors on and off (switching operation).

More specifically, the inverter circuit 2a includes switching legs corresponding to the U, V, and W phases of the motor 3, respectively. As illustrated in FIG. 1, the switching legs corresponding to the respective phases each includes two drive transistors (hereinafter also referred to as “switching element”) Q1 and Q2, Q3 and Q4, Q5 and Q6 connected in series between the DC power supply Vin and the ground potential via the current detection circuit 2c.

Here, the drive transistors Q1, Q3, and Q5 (corresponding to high side switches) of the upper arms of the coils of the motor 3 are, for example, N-channel MOSFETs. The drive transistors Q2, Q4, and Q6 (corresponding to low side switches) of the lower arms of the coils of the motor 3 are, for example, N-channel MOSFETs. The drive transistors Q1 to Q6 may be other types of FETs, and may be other types of transistors, for example, such as IGBT (Insulated Gate Bipolar Transistor).

For example, the switching leg corresponding to the U-phase includes the switching elements Q1 and Q2 connected in series with each other. The point commonly connecting a switching element Q1 and a switching element Q2 is connected to one end of the coil Lu as a load. The switching leg corresponding to the V-phase includes the switching elements Q3 and Q4 connected in series with each other. The point commonly connecting the switching element Q3 and switching element Q4 is connected to one end of the coil Lv as a load. The switching leg corresponding to the W-phase includes the switching elements Q5 and Q6 connected in series with each other. The point commonly connecting the switching element Q5 and the switching element Q6 is connected to one end of the coil Lw as a load. The switching elements Q1 and Q2, Q3 and Q4, Q5 and Q6 each has parasitic diode characteristics in the direction from the ground side to the power supply side (not illustrated in FIG. 1).

The pre-drive circuit 2b generates a drive signal for driving the inverter circuit 2a based on the drive control signal Sd output from the control circuit 1.

The drive control signal Sd is a signal for controlling the drive of the motor 3, for example, a Pulse Width Modulation (PWM) signal. Specifically, the drive control signal Sd is a signal for switching the energization patterns of the coils Lu, Lv, and Lw of the motor 3 determined by the on/off state of each switching element constituting the inverter circuit 2a. More specifically, the drive control signal Sd includes six PWM signals corresponding to the switching elements Q1 to Q6 of the inverter circuit 2a, respectively.

Based on the six PWM signals as the drive control signal Sd supplied from the control circuit 1, the pre-drive circuit 2b generates six drive signals Vuh, Vul, Vvh, Vvl, Vwh, and Vwl capable of providing sufficient power to drive the control electrodes (gate electrodes) of the respective switching elements Q1 to Q6 of the inverter circuit 2a.

When these drive signals Vuh, Vul, Vvh, Vvl, Vwh, and Vwl are input to the control electrodes (gate electrodes) of the respective switching elements Q1 to Q6 of the inverter circuit 2a, the switching elements Q1 to Q6 each performs on/off operation (switching operation). For example, at the switching leg corresponding to each phase, each of the switching elements Q1, Q3, and Q5 of the upper arm and a corresponding one of the switching elements Q2, Q4, and Q6 of the lower arm, alternately performs on/off operations. As a result, the DC power supply Vin supplies power to each phase of the motor 3, and the motor 3 rotates.

The current detection circuit 2c is connected to a DC line of the inverter circuit 2a and detects the current flowing through the DC line. Specifically, the current detection circuit 2c includes one resistor (hereinafter also referred to as “shunt resistor”) Rs as a current detection element. A shunt resistor Rs is connected in series with the inverter circuit 2a, for example, between the DC power supply Vin and the ground potential. That is, the shunt resistor Rs of the current detection circuit 2c is connected to the negative side (ground side) of the inverter circuit 2a, for example, as illustrated in FIG. 1. In driving the motor, the inverter circuit 2a is controlled, and the winding currents Iu, Iv, Iw of the respective phases flowing to the respective coils Lu, Lv, and Lw of the three-phase coils of the motor 3 flow to the shunt resistor Rs of the current detection circuit 2c. The current detection circuit 2c detects the voltage drop caused by the current flowing through the shunt resistor Rs from the differential voltage between both ends of the shunt resistor Rs, and outputs a shunt current detection signal Vs corresponding to the current flowing through the shunt resistor Rs to the control circuit 1 as the detection result. The shunt resistor Rs can function as an overcurrent detection circuit, as described below.

A wiring (hereinafter also referred to as “phase voltage detection circuit”) for measuring phase voltage Vu, Vv, Vw generated in each phase is connected between the inverter circuit 2a and the coil Lu, Lv, Lw of the corresponding phase of the motor 3, and is input to the control circuit 1. In the control circuit 1, the differential voltage (difference voltage between a neutral point voltage and the phase voltage of a selected one phase: value according to the phase voltage of the selected phase) measured based on the phase voltage Vu, Vv, and Vw generated at each phase is utilized in the drive control of the motor and the idling detection of the motor, described below.

In the drive of the motor, the control circuit 1 generates the drive control signal Sd for driving the motor 3 based on, for example, the speed command signal Sc, input from the outside and indicating the target state of the operation of the motor 3, and controls the drive of the motor 3. Specifically, the control circuit 1 generates the drive control signal Sd so that the motor 3 becomes the operation state specified by the speed command signal Sc then provided to the drive circuit 2.

In the idling detection of the motor, the control circuit 1 generates the idling control signal Id described below instead of the drive control signal Sd to detect the idling of the motor 3. Specifically, when the motor 3 is not driven by the drive control signal Sd, the control circuit 1 generates the idling control signal Id so that each of the switching elements Q1 to Q6 of the inverter circuit 2a is in the switch state specified by the idling control signal Id then provided to the drive circuit 2.

Here, the switch state of each of the switching elements Q1 to Q6 of the inverter circuit 2a corresponding to the three modes (free mode, charge mode, discharge mode), detecting the idling of the motor 3 and switched by the idling control signal Id generated by the control circuit 1, will be described.

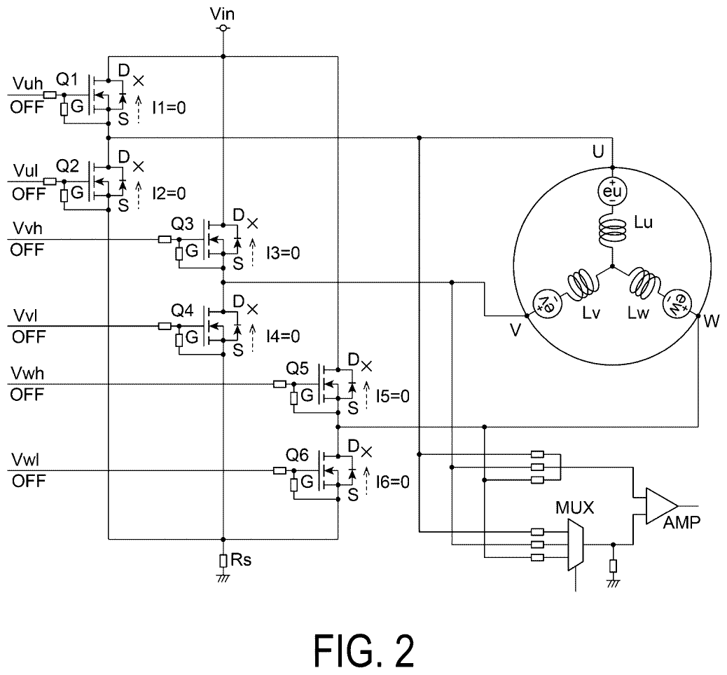

FIGS. 2 to 4 are diagrams for describing the switch states switched by the idling control signal Id, respectively. In FIGS. 2 to 4, the state of the current flowing when the motor 3 is idling at the coils of the motor 3 and the inverter circuit 2a, is indicated by an arrow. The inverter circuit 2a is connected to the DC power supply Vin and connected to the ground via the shunt resistor Rs, a part of the current detection circuit 2c. In addition, a wiring (phase voltage detection circuit) for measuring each of the phase voltages Vu, Vv, Vw by the control circuit 1 is connected between the corresponding phase of the coil of the motor 3 and the inverter circuit 2a.

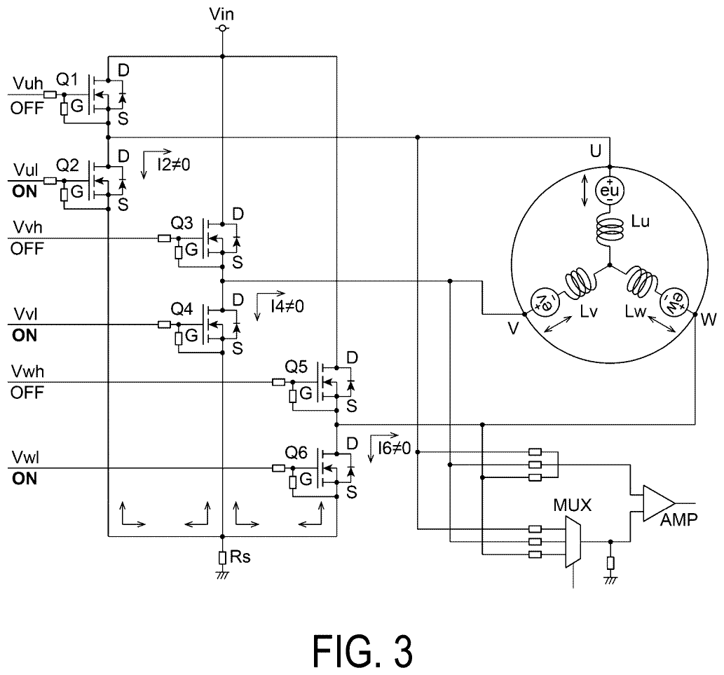

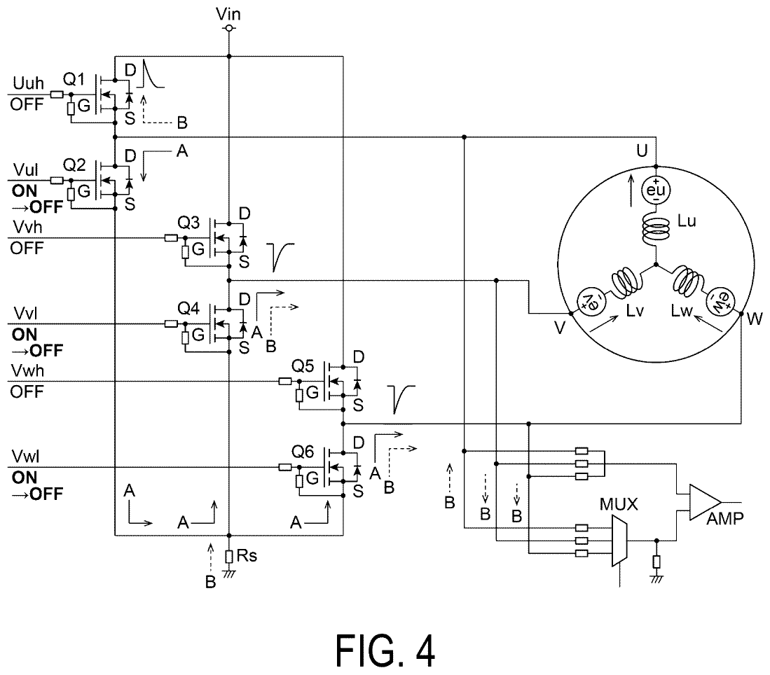

The idling control signal Id is a signal for switching to the corresponding switch state in the order of the free mode (FIG. 2), the charge mode (FIG. 3), and the discharge mode (FIG. 4). Specifically, the idling control signal Id sets the switch state of the control electrode (gate electrode) of each of the switching elements Q1 to Q6 of the inverter circuit 2a from the first switch state (corresponding to the free mode) illustrated in FIG. 2 to the second switch state (corresponding to the charge mode) illustrated in FIG. 3, and switches to the first switch state (corresponding to the discharge mode) again as illustrated in FIG. 4, thereby enabling to detect the idling of the motor 3.

### Free Mode

When the idling control signal Id is output from the control circuit 1 at a predetermined timing after the power is turned on, the control electrodes (gate electrodes) of the respective switching elements Q1 to Q6 of the inverter circuit 2a are switched to the first switch state by the idling control signal Id output from the control circuit 1. Specifically, as illustrated in FIG. 2, at the inverter circuit 2a, all switch states of the switching elements Q1 to Q6 are switched off.

As illustrated in FIG. 2, in this first switch state, when the rotor of the motor 3 is idling, an induced electromotive force is generated at the coil of each phase, and a voltage is generated at the phase voltage detection circuit. However, the induced current circulating between each coil of the motor 3 and the inverter circuit 2a is not generated due to the switching elements Q1 to Q6 off and the clamping of the parasitic diode. At this time, an induced voltage is generated at the phase voltage detection circuit in accordance with the idling rotation speed.

### Charge Mode

Next, the idling control signal Id output from the control circuit 1 switches the control electrodes (gate electrodes) of the respective switching elements Q1 to Q6 of the inverter circuit 2a from the first switch state to the second switch state. In the second switch state, when the rotor of the motor 3 is idling, an induced electromotive force is generated in the coil of each phase, and the generated induced currents circulate at the closed circuit formed by the coils and the switched elements turned on among the switching elements Q1 to Q6. Specifically, at the inverter circuit 2a, the first switch state turning off all the switch states of the switching elements Q1 to Q6 is switched to the second switch state turning on the switch states of only the switching elements Q2, Q4, and Q6 of the lower arms of the switching elements Q1 to Q6, for example, as illustrated in FIG. 3.

As illustrated in FIG. 3, at the inverter circuit 2a, once the second switch state is reached turning on the switch states of the switching elements Q2, Q4, and Q6 of the lower arms of the switching elements Q1 to Q6, when the rotor of the motor 3 is idling, induced currents circulating between the coils of the motor 3 and the inverter circuit 2a are generated at the coils of respective phases, and the generated induced currents are circulated at the closed circuit formed by the coils and the switching elements Q2, Q4, and Q6 of the turned on lower arms. However, at this time, no induced voltage is generated at the phase voltage detection circuit.

Specifically, when the motor is idling, an induced voltage (eu, ev, ew) proportional to the rotation speed is generated at the coil of each phase by the rotation of the rotor relative to the coil for the electric angular period of the motor rotation with each phase shifted by 120 degrees, with polarity in the direction of generating a current preventing the change of magnetic flux. At this time, the current waveform has a phase delayed by 90 degrees relative to the voltage waveform.

### Discharge Mode

Next, the idling control signal Id output from the control circuit 1 switches the control electrodes (gate electrodes) of the respective switching elements Q1 to Q6 of the inverter circuit 2a from the second switch state to the first switch state again. Specifically, for example, at the inverter circuit 2a, the second switch state turning on the respective switch states of only the switching elements Q2, Q4, and Q6 of the lower arms of the switching elements Q1 to Q6 is switched again to the first switch state turning off all the switch states of the switching elements Q1 to Q6, as illustrated in FIG. 4.

As illustrated in FIG. 4, when the rotor of the motor 3 is idling, the paths of the circulating induced currents are cut off at the inverter circuit 2a once the motor 3 enters the first switch state from the second switch state. At this time, the coil of the winding of the motor 3 generates an inductive kickback (B in FIG. 4) at the inverter circuit 2a because the induced current (A in FIG. 4) circulating through the coil attempts to continue flowing through the coil. Specifically, a voltage rise occurs at the connection point between the upper arm and the lower arm of the leg of the phase downstream of the induced current, and a voltage drop occurs at the connection point between the upper arm and the lower arm of the leg of the phase upstream of the induced current. This voltage fluctuation is clamped by the parasitic diode of each switching element Q1 to Q6, so that due to the DC power supply Vin and a forward voltage Vf of the parasitic diode when the number of phases of the motor is three, depending on the position of the rotor, the phase voltage of the phase at the most downstream side of the induced current rises to Vin+Vf, the phase voltage of the phase at the most upstream side of the induced current falls to −Vf, and the phase voltages of the remaining phases rise to Vin+Vf or fall to −Vf depending on the direction of the induced current. In addition, the voltage fluctuation is short, and when the motor has three phases, the voltage fluctuation time of the most downstream phase and the most upstream phase of the induced current is the longest, depending on the position of the rotor. At this time, the phase voltage detection circuit also experiences voltage fluctuation due to the inductive kickback. This voltage fluctuation also occurs when the coil is of one phase and the switching elements are provided above and below both ends of the coil.

At the motor drive control device 10 of the present embodiment, when the voltage generated at the phase voltage detection circuit is detected and the voltage fluctuation due to the inductive kickback is determined to have occurred, the motor 3 can be determined to be idling.

In the description in the above example, as the second switch state corresponding to the charge mode, as illustrated in FIG. 3, all switch states of the switching elements Q2, Q4, and Q6 of the lower arm among the switching elements Q1 to Q6 of the inverter circuit 2a are turned on, but it is not limited to this example. All switch states of the switching elements Q1, Q3, and Q5 of the upper arm among the switching elements Q1 to Q6 of the inverter circuit 2a may be turned on.

The idling control signal Id is a signal for switching each of the switching elements constituting the inverter circuit 2a to switch states corresponding to the three modes for detecting the idling of the motor 3. Unlike the drive control signal Sd for driving the motor, the idling control signal Id is not a signal for generating a driving voltage to the coils of the motor 3, so that the idling control signal Id is not a signal for alternately switching the switching elements on and off, but a high or low signal having a predetermined length, for example. The idling control signal Id includes six types of signals corresponding to the respective switching elements Q1 to Q6 of the inverter circuit 2a.

Based on the idling control signal Id output from the control circuit 1, the pre-drive circuit 2b generates a drive signal as a switch signal for switching the switch state of each of the switching elements constituting the inverter circuit 2a.

Based on the six types of signals as the idling control signal Id supplied from the control circuit 1, the pre-drive circuit 2b generates a signal capable of supplying sufficient power to switch the switch states of the control electrodes (gate electrodes) of the respective switching elements Q1 to Q6 of the inverter circuit 2a. As these switching signals, the drive signals are input to the control electrodes (gate electrodes) of the respective switching elements Q1 to Q6 of the inverter circuit 2a, thereby switching the switch states of the respective switching elements Q1 to Q6. Details of the idling control signal Id will be described below.

In an embodiment, the control circuit 1 is a program processing device (e.g., a microcontroller) having a configuration. In the configuration, for example, a processor such as a CPU, various storage devices such as RAM and ROM, and peripheral circuits such as a counter (timer), an A/D conversion circuit, a D/A conversion circuit, a clock generation circuit, and an input/output I/F circuit are connected to each other via a bus or a dedicated line.

The motor drive control device 10 may have a configuration packaging, at least a part of the control circuit 1 and at least a part of the drive circuit 2 as one integrated circuit device (IC), or may have a configuration packaging the control circuit 1 and the drive circuit 2 as individually integrated circuit devices.

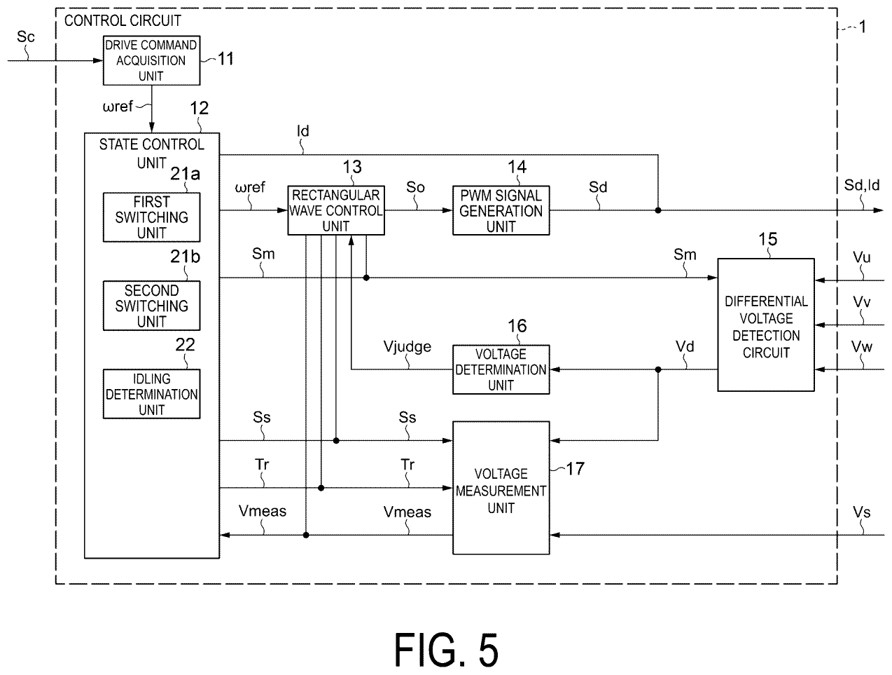

FIG. 5 is a diagram illustrating a function block configuration of the control circuit 1 at the motor drive control device 10 according to the embodiment.

As illustrated in FIG. 5, the control circuit 1 includes, for example, a drive command acquisition unit 11, the state control unit 12, a rectangular wave control unit 13, a PWM signal generation unit 14, the differential voltage detection circuit 15, a voltage determination unit 16, and the voltage measurement unit 17 as functional blocks for generating the drive control signal Sd in driving the motor by a 120 degree energized square wave drive method. The control circuit 1 includes the state control unit 12, the differential voltage detection circuit 15, and the voltage measurement unit 17 as functional blocks for generating the idling control signal Id in the idling detection of the motor. The state control unit 12 includes a first switching unit 21a, a second switching unit 21b, and an idling determination unit 22.

These functional blocks are achieved, for example, at a program processor as the control circuit 1, by the processor executing various arithmetic operations according to a program stored at a memory and controlling peripheral circuits such as a counter and A/D conversion circuit.

The drive command acquisition unit 11 receives the speed command signal Sc from the outside and analyzes the received speed command signal Sc to acquire a value specifying a target operation state of the motor 3 specified by the speed command signal Sc.

The speed command signal Sc includes a value indicating a target operation state of the motor 3. The speed command signal Sc is, for example, a signal output from a host device, provided outside the motor drive control device 10 and for controlling the motor unit 100.

In an embodiment, the speed command signal Sc specifies, for example, the rotation speed of the rotor of the motor 3. The speed command signal Sc includes a value ωref of the rotation speed as a target (target rotation speed) of the rotor of the motor 3.

The speed command signal Sc is, for example, a PWM signal having a duty ratio corresponding to the specified target rotation speed ωref. The drive command acquisition unit 11 measures, for example, the duty ratio of the PWM signal of the speed command signal Sc and outputs the rotation speed corresponding to the measured duty ratio as the target rotation speed ωref.

The state control unit 12 directly outputs the target rotation speed ωref to the rectangular wave control unit 13 in driving the motor. The state control unit 12 can determine how to start the motor when the idling determination signal described below is generated from the idling determination unit 22. Although not specifically illustrated in FIG. 5, the state control unit 12 may further include a function unit for executing such process.

In driving the motor, the rectangular wave control unit 13 outputs a drive command signal So to the PWM signal generation unit 14, outputs the measurement phase selection signal Sm to the differential voltage detection circuit 15, and outputs the measurement type selection signal Ss and a measurement trigger signal Tr to the voltage measurement unit 17. The measurement phase selection signal Sm is a signal for selecting a phase to be detected at the differential voltage detection circuit 15 among the coil phases of the motor. The measurement type selection signal Ss is a signal for selecting the type of measurement at the voltage measurement unit 17, and for example, a signal for selecting whether the input shunt current detection signal Vs or a differential voltage detection signal Vd is to be detected at the voltage measurement unit 17 described below. The measurement trigger signal Tr is a signal for triggering the measurement at the voltage measurement unit 17, and for example, a signal for turning on and off a sampling circuit 172 within the voltage measurement unit 17 described below.

The rectangular wave control unit 13, in order to obtain the switching timing of the 6 energization directions in the drive control method using a 120 degree square wave in driving the motor, outputs the measurement phase selection signal Sm corresponding to the non-energization phase (induced voltage phase) to the differential voltage detection circuit 15. Then, the rectangular wave control unit 13 receives a voltage determination signal Vjudge, indicating the timing of the zero-cross, determined by the voltage determination unit 16, of the differential voltage between the induced voltage of the selected non-energization phase and the neutral point voltage. Then the rectangular wave control unit 13 adjusts the energization switching in the drive control.

The rectangular wave control unit 13, in driving the motor, generates the drive command signal So from the target rotation speed ωref and the voltage determination signal Vjudge in accordance with the drive control method using a 120 degree square wave, then output to the PWM signal generation unit 14 to drive and control the motor. The voltage determination signal Vjudge is a signal indicating the timing of the zero-cross determined by the voltage determination unit 16. The rectangular wave control unit 13 performs motor drive control by, for example:
energizing the windings from the U-phase to the V-phase by two phase excitation;
measuring the differential voltage between the induced voltage (phase voltage) generated in the W-phase of the non-energized phase and the neutral point voltage at the differential voltage detection circuit 15; and
switching the energization by using the timing of the zero-cross, as a comparison result between the output value of a D/A converter 161 for comparator and the differential voltage detection signal Vd and determined by the voltage determination unit 16 described below. In this case, Vin (DC power supply)/2 may be used for the neutral point voltage instead of the voltage obtained by combining the phase voltages of all phases.

The rectangular wave control unit 13 outputs the measurement trigger signal Tr and the measurement type selection signal Ss to the voltage measurement unit 17 in order to detect whether an overcurrent is generated at the inverter circuit in driving the motor, receives the voltage measurement value Vmeas corresponding to the shunt current detection signal Vs measured at the voltage measurement unit 17 at a predetermined timing, and detects the overcurrent based on the voltage measurement value Vmeas. When the overcurrent is detected, the drive command signal So may be adjusted in order to control the driving of the motor corresponding to the overcurrent.

In driving the motor, the PWM signal generation unit 14 generates the drive control signal Sd according to the drive command signal So received from the rectangular wave control unit 13, thereby output to the drive circuit 2 and performing PWM control of the drive circuit 2.

The differential voltage detection circuit 15 is configured to output the phase voltage of the selected phase as the differential voltage detection signal Vd to the voltage determination unit 16 and the voltage measurement unit 17.

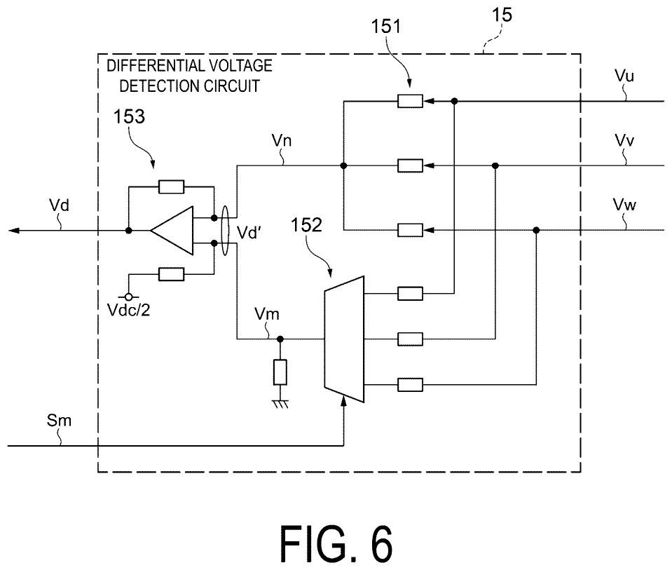

FIG. 6 illustrates an example of the configuration of the differential voltage detection circuit 15. Here, the example of the configuration of the differential voltage detection circuit 15 will now be described.

The differential voltage detection circuit 15 receives input of the phase voltage Vu, Vv, Vw of each phase and the measurement phase selection signal Sm are input, and outputs the differential voltage detection signal Vd. The differential voltage detection circuit 15 is composed of a plurality of resistance elements 151 for limiting DC current and adjusting voltage, a measurement phase selection multiplexer (MUX) 152, and a differential amplifier circuit 153. The differential voltage detection circuit 15 branches the phase voltage Vu, Vv, and Vw inputs of each phase into two, synthesizes one of the branches, and inputs the one to the differential amplifier circuit 153 as a composite signal (neutral point voltage) Vn, and inputs the other to a measurement phase selection multiplexer 152. The output from the measurement phase selection multiplexer 152 is also input to the differential amplifier circuit 153.

In the differential voltage detection circuit 15, the measurement phase selection multiplexer 152 selects one of the three phase voltages Vu, Vv, Vw according to the measurement phase selection signal Sm input from the state control unit 12 or the rectangular wave control unit 13 and outputs the selected one, as a selected phase voltage signal Vm, to the differential amplifier circuit 153. The voltage corresponding to the phase voltage of the selected phase and the composite signal Vn of the three phase voltages Vu, Vv, Vw corresponding to the neutral point voltage of the motor coil, are input to the differential amplifier circuit 153. That is, the signal corresponding to the differential voltage detection signal Vd′ is input to the differential amplifier circuit 153. The differential voltage detection signal Vd′ generated from the selected phase voltage signal Vm and a neutral point voltage Vn has both positive and negative polarities in driving the motor and in detecting the motor's idling, the differential amplifier circuit 153 expands and contracts (amplifies and reduces) the signal and shifts by the DC power supply Vdc/2, and outputs the signal as the differential voltage detection signal Vd almost similar to the differential voltage detection signal Vd′ and saturated in the voltage range from 0 V to Vdc centered at Vdc/2. That is, the differential voltage detection signal Vd is a signal corresponding to the phase voltage of the selected phase.

The voltage determination unit 16 is a comparator comparing the voltage of a predetermined signal with the input signal, and is configured to determine the zero-cross of the differential voltage between the induced voltage and the neutral point voltage in driving the motor.

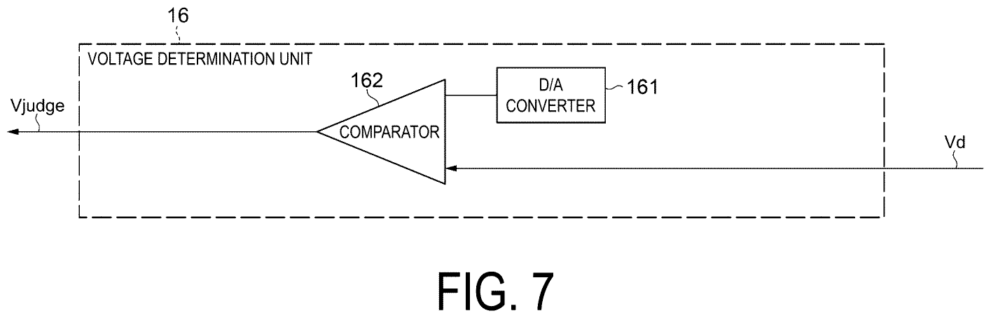

FIG. 7 is a diagram illustrating an example of the configuration of the voltage determination unit 16. Here, the example of the configuration of the voltage determination unit 16 will be described. As illustrated in FIG. 7, for example, the voltage determination unit 16 includes the D/A converter 161 for comparator and a comparator 162.

In driving the motor, the voltage determination unit 16 determines the zero-cross of the differential voltage between the induced voltage and the neutral point voltage based on the differential voltage detection signal Vd corresponding to the phase voltage of the selected phase. The differential voltage detection signal Vd shifts by Vdc/2 at the differential voltage detection circuit 15, so that the D/A converter 161 for comparator inputs a predetermined zero-cross reference value using Vdc/2 as an analog signal to the comparator 162 at the voltage determination unit 16. The comparator 162 compares the predetermined zero-cross reference signal input from the D/A converter 161 for comparator with the differential voltage detection signal Vd, switches the signal output as the comparison result at a timing when the value of the differential voltage detection signal Vd relative to the zero-cross reference signal changes from the high-voltage side to the low-voltage side or from the low-voltage side to the high-voltage side, and outputs a signal indicating the timing of the zero-cross to the rectangular wave control unit 13 as the voltage determination signal Vjudge.

The voltage measurement unit 17 is an A/D converter for quantifying the voltage of the input signal selected by the multiplexer, and is configured to output the voltage measurement value Vmeas corresponding to the differential voltage detection signal Vd or the shunt current detection signal Vs to the state control unit 12 and the rectangular wave control unit 13.

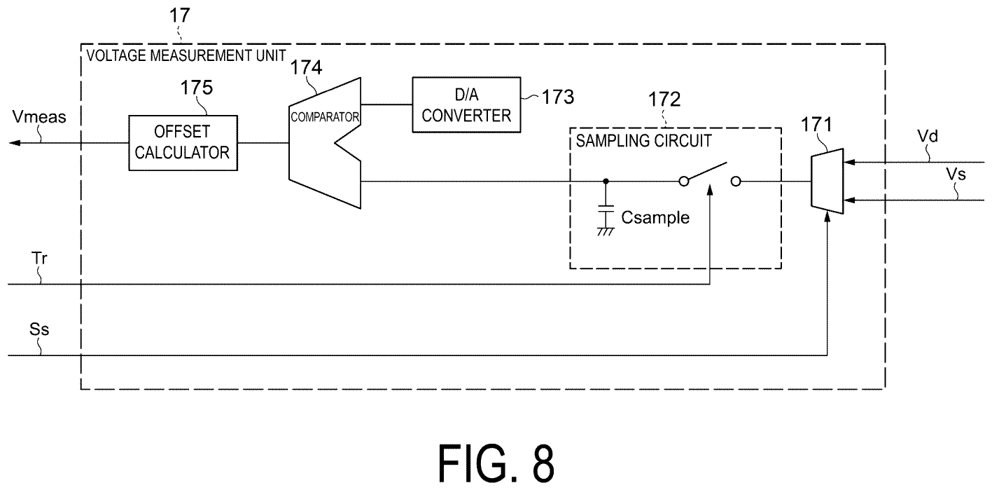

FIG. 8 illustrates an example of the configuration of the voltage measurement unit 17. Here, the example of the configuration of the voltage measurement unit 17 will be described. As illustrated in FIG. 8, for example, the voltage measurement unit 17 includes a measurement type selection multiplexer 171, the sampling circuit 172, a D/A converter 173 for A/D converter, a comparator 174, and an offset calculator 175.

The voltage measurement unit 17 selects either the differential voltage detection signal Vd or the shunt current detection signal Vs in accordance with the measurement type selection signal Ss, performs an A/D conversion for the voltage in the selected detection signal using the measurement trigger signal Tr as a trigger, and performs ADC voltage measurement. The voltage measurement value Vmeas obtained by performing the ADC offset adjustment described below is output to the state control unit 12 and the rectangular wave control unit 13.

The voltage measurement unit 17 measures the voltage measurement value Vmeas corresponding to the shunt current detection signal Vs in accordance with the measurement type selection signal Ss and measurement trigger signal Tr input from the rectangular wave control unit 13 for overcurrent detection in driving the motor, and the voltage measurement value Vmeas is output to the rectangular wave control unit 13.

The voltage measurement unit 17 measures the voltage measurement value Vmeas corresponding to the differential voltage detection signal Vd in accordance with the measurement type selection signal Ss and measurement trigger signal Tr input from the state control unit 12 for idling detection after the power is turned on or at the idling determination timing, and outputs the measured Vmeas to the state control unit 12.

The ADC offset adjustment at the voltage measurement unit 17 will now be described. When the differential voltage detection signal Vd is selected by the measurement type selection signal Ss, the differential voltage detection signal Vd generated from the selected phase voltage signal Vm and the neutral point voltage Vn at the differential voltage detection circuit 15 becomes a signal saturated in the voltage range from 0 V to Vdc centered at Vdc/2 by the differential amplifier circuit 153. Thus, the zero point of the differential voltage detection signal Vd is clarified by securing in advance the value of the voltage measurement value Vmeas, in the charge mode as a state with the phase voltage not generated, and adjusting the ADC offset.

ADC offset adjustment at the voltage measurement unit 17 is performed in the same manner when the shunt current detection signal Vs is selected by the measurement type selection signal Ss. The shunt current detection signal Vs may become a non-zero value due to shift or bias voltage when no shunt current is generated. Thus, the zero point of the shunt current detection signal Vs is clarified by securing in advance the value of the voltage measurement value Vmeas, in the free mode or charge mode as a state with the shunt current not generated, and adjusting the ADC offset.

To adjust the ADC offset, the state control unit 12 inputs the measurement trigger signal Tr to the voltage measurement unit 17 in a state with the differential voltage detection signal Vd essentially zero. The voltage measurement unit 17, triggered by the measurement trigger signal Tr, performs an A/D conversion on the signal input to the sampling circuit 172 to perform the ADC voltage measurement. The difference between the measured value and “0” is calculated to be the ADC offset adjustment value. This ADC offset adjustment value is used by the offset calculator 175 of the voltage measurement unit 17 to execute the ADC offset adjustment.

The idling determination controlled by the state control unit 12 will now be described further.

At the state control unit 12, when the motor idling is detected, the idling control signal Id is generated to switch to the first switch state by the first switching unit 21a, to switch to the second switch state by the second switching unit 21b and is output to the drive circuit 2. The start of the generation of the idling control signal Id can be triggered by the power being turned on or the receipt of the speed command signal Sc after the motor has stopped (a predetermined time has elapsed since the interruption of the speed command signal Sc).

At the state control unit 12, the first switching unit 21a generates the idling control signal Id switching the switching elements Q1 to Q6 constituting the inverter circuit 2a to the first switch state. At the state control unit 12, the second switching unit 21b generates the idling control signal Id switching the switching elements Q1 to Q6 constituting the inverter circuit 2a to the second switch state. The idling control signal Id generated by the first switching unit 21a and the second switching unit 21b of the state control unit 12 is output to the drive circuit 2.

The state control unit 12 performs ADC offset measurement of the differential voltage detection signal Vd in a state with no phase voltage generated while switching to a predetermined switch state after the power supply is turned on, in order to make the switch state capable of idling detection. After the ADC offset measurement, until the speed command signal Sc is received at the drive command acquisition unit 11, the idling control signal Id corresponding to the free mode is generated by the first switching unit 21a, waiting for the start to drive the motor. Thereafter, at the state control unit 12, in order to detect whether the motor is in the idling state immediately before driving the motor by the input of the speed command signal Sc, the idling control signal Id is generated by the second switching unit 21b during the charge time (period corresponding to the charge mode). Further thereafter, at the state control unit 12, the idling control signal Id is generated by the first switching unit 21a during the discharge time (period corresponding to the discharge mode). After the discharge time completing the idling determination, the idling control signal Id corresponding to the free mode may again be generated by the first switching unit 21a. In addition, the charge mode and the discharge mode may again be executed in order to detect again whether the motor is idling.

The timing of the transition from the free mode to the charge mode may be, for example, after the drive command acquisition unit 11 receives the speed command signal Sc.

The state control unit 12 instructs the voltage measurement unit 17 to measure the input differential voltage detection signal Vd by outputting the measurement type selection signal Ss for selecting the differential voltage detection signal Vd by the measurement type selection multiplexer 171 and the measurement trigger signal Tr for turning on the sampling circuit 172 and detecting the idling, at the timing just before the transition from the charge mode to the discharge mode, i.e., in a state with the phase voltage not occurring just before the switch from the second switch state to the first switch state, in the idling detection of the motor. Based on the instruction from the state control unit 12, the voltage measurement unit 17 performs A/D conversion on the input differential voltage detection signal Vd and further performs ADC offset adjustment to generate the voltage measurement value Vmeas. The voltage measurement unit 17 outputs the generated voltage measurement value Vmeas to the idling determination unit 22 of the state control unit 12. This voltage measurement value Vmeas is used as the reference voltage. After the measurement of the differential voltage detection signal Vd, the mode shifts to the discharge mode.

The state control unit 12 switches from the second switch state to the first switch state when the motor is in the discharge mode in the idling detection. Then, the state control unit 12 instructs the voltage measurement unit 17 to measure the inputted differential voltage detection signal Vd by outputting the measurement type selection signal Ss for selecting the differential voltage detection signal Vd at the measurement type selection multiplexer 171 and the measurement trigger signal Tr, turning on the switch of the sampling circuit 172 and for idling detection, at a predetermined timing after the lapse of a short mask time to avoid the influence of switching of the switching element. Based on the instruction from the state control unit 12, the voltage measurement unit 17 performs A/D conversion on the input differential voltage detection signal Vd and further performs ADC offset adjustment to generate the voltage measurement value Vmeas. The voltage measurement unit 17 outputs the generated voltage measurement value Vmeas to the idling determination unit 22 of the state control unit 12. This voltage measurement value Vmeas is used as the measured voltage. The measurement of the differential voltage detection signal Vd is performed a plurality of times during the period of the discharge mode.

The idling determination unit 22 determines whether the motor 3 is idling based on the voltage measurement value Vmeas generated by the voltage measurement unit 17, and generates an idling determination signal indicating the idling determination result. Specifically, the idling determination unit 22 uses the voltage measurement values Vmeas, as the measured voltages, obtained by instructing the voltage measurement unit 17 to measure at a plurality of timings, calculates the maximum fluctuation voltage difference maximizing the difference between the reference voltage and the measured voltage. Then, the idling determination unit 22 compares the calculated maximum fluctuation voltage difference with a preset threshold (idling threshold), and determines idling of the motor 3 when the maximum fluctuation voltage difference is greater than the idling threshold.

The idling threshold value can utilize the value of the maximum fluctuation voltage difference with the difference between the reference voltage of the differential voltage detection signal Vd and the measured voltage being the maximum at the minimum rotation speed (minimum idling rotation speed) for idling detection.

As for the charge time, since the voltage fluctuation time generated at the phase voltage detection circuit by the inductive kickback varies according to the rotation speed and the rotor position, the time previously measured so that the minimum voltage fluctuation time at the minimum rotation speed (minimum rotation speed) for idling detection can be measured, may be utilized. As the charge time is shortened, the idling detection period is shortened, and the abnormal noise of the drive system due to the short brake state of the charge time is reduced, thereby desirable.

As for the discharge time, the voltage fluctuation generated at the phase voltage detection circuit by the inductive kickback decays over time and converges to a predetermined value, thus the pre-measured time may be used so that the differential voltage detection signal Vd can be measured over a plurality of times at the minimum rotation speed (minimum rotation speed) for idling detection. In addition, when the maximum fluctuation voltage difference with the difference between the reference voltage and the measured voltage of the differential voltage detection signal Vd measured over a plurality of times being the maximum is measured, the measurement may be terminated without waiting for the passage of the discharge time.

Next, the transition of the mode after turning on the power of the state control unit 12 will be described in detail.

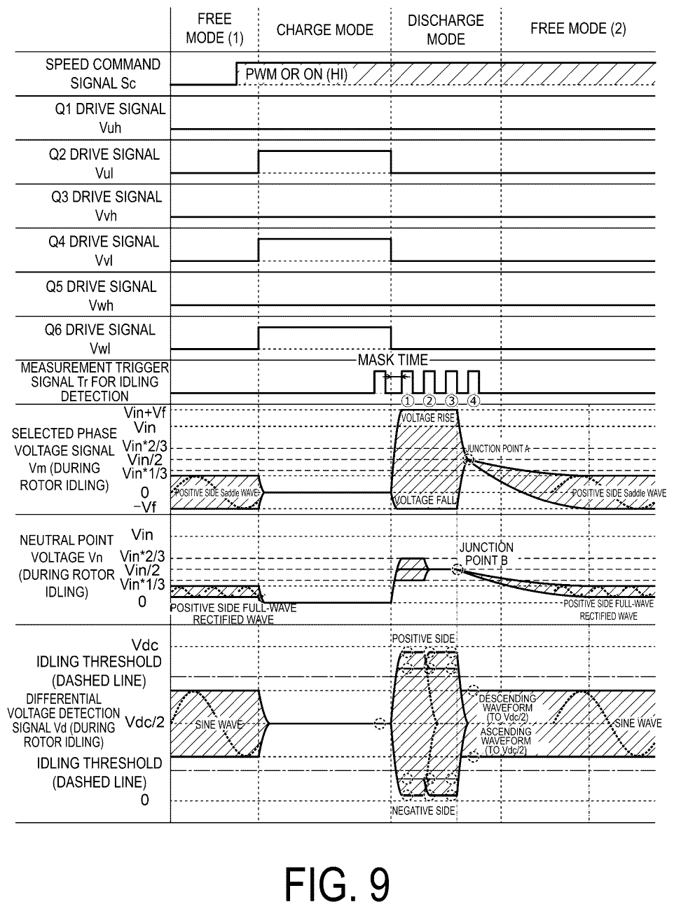

FIG. 9 is a timing chart illustrating an example of a signal waveform until the speed command signal Sc is input and the determination of idling is completed, after the power of the motor unit 100 is turned on.

FIG. 9 illustrates, from top to bottom: the respective waveforms of the speed command signal Sc, the respective drive signals input to the gates of switching elements Q1 to Q6, and the measurement trigger signal Tr for idling detection; and the respective waveforms of the selected phase voltage signal Vm being a phase voltage selected from the three phase voltages Vu, Vv, and Vw, the neutral point voltage Vn generated by the three phase voltages Vu, Vv, and Vw, and the differential voltage detection signal Vd output from the differential voltage detection circuit 15.

The speed command signal Sc is a signal received as the target rotation speed ωref at the state control unit 12, and the state control unit 12 generates the idling control signal Id including the respective drive signals input to the gates of switching elements Q1 to Q6 and the measurement trigger signal Tr for idling detection input to the voltage measurement unit 17 at a predetermined timing, triggered by the power-on or reception of the speed command signal Sc.

The measurement phase selection signal Sm is generated by the state control unit 12, so that the selected phase voltage signal Vm and the neutral point voltage Vn are input to the differential amplifier circuit 153, and as a result, the differential voltage detection circuit 15 outputs the differential voltage detection signal Vd.

As illustrated in FIG. 9, the motor drive control device 10 is illustrated to return to the free mode after going through the free mode, charge mode, and discharge mode. At this time, the motor drive control device 10 starts from the free mode (free mode (1)) after turning on the power. In the timing chart illustrated in FIG. 9, a case returning to the free mode (free mode (2)) after the discharge mode is taken as an example, but not limited to this case.

In the free mode, the inverter circuit 2a is set to the first switch state by the idling control signal Id. Specifically, in response to the idling control signal Id generated by the first switching unit 21a, all the drive signals input to the gates of switching elements Q1 to Q6 constituting the inverter circuit 2a are set to low, and all switches of the inverter circuit are turned off. In this state, the closed circuit is not constituted, so that the winding current of the selected phase is 0 A, and no current flows.

In this state, when the rotor of the motor 3 is idling, the induced electromotive forces are generated at the coils of the motor 3. Because all the switching elements Q1 to Q6 are turned off, the phase voltage Vu of the U-phase, the selected phase voltage signal Vm, oscillates with a positive side saddle wave of the amplitude due to the induced voltage according to the idling rotation speed and the period according to the idling rotation speed, due to the influence of the clamp of the parasitic diode. The positive side saddle wave means a waveform with a recess at the apex at the positive side arc similar to the full-wave rectified wave. Due to all the switching elements Q1 to Q6 turned off, the neutral point voltage Vn synthesized by the phase voltages of all the phases, oscillates with a full-wave rectified wave at the positive side with an amplitude due to the induced voltage according to the idling rotation speed and a period of three times the phase voltage. A positive-side full-wave rectified wave means a full-wave rectified wave with an arc apex at the positive side. The differential voltage detection signal Vd′ between the selected phase voltage signal Vm and the neutral point voltage Vn, both input to the differential amplifier circuit 153, oscillates with a sine wave of an amplitude due to the induced voltage according to the idling rotation speed and a period according to the idling rotation speed by turning off all the switching elements Q1 to Q6. At this time, the differential voltage detection signal Vd becomes a signal almost similar to the differential voltage detection signal Vd′, and the signal is saturated in the voltage range from 0 V to Vdc centered at Vdc/2, by the differential amplifier circuit 153.

Next, in the charge mode, the inverter circuit 2a is set to the second switch state by the idling control signal Id. Specifically, by the idling control signal Id generated by the second switching unit 21b, all the drive signals input to the gates of the switching elements Q2, Q4, and Q6 of the lower arms of the switching elements Q1 to Q6 constituting the inverter circuit 2a are set to high, and all the low side switches of the inverter circuit are turned on.

In this state, when the rotor of the motor 3 is idling, induced electromotive forces are generated at the coils of the motor 3, and as illustrated in FIG. 3, a closed circuit is formed between the coils of the motor 3 and the switching elements Q2, Q4, and Q6 turned on at the inverter circuit 2a. Then, currents circulating between the coils of the motor 3 and the inverter circuit 2a are generated, and the winding current of the selected phase oscillates with a sine wave with an amplitude due to the induced current corresponding to the idling rotation speed and a period corresponding to the idling rotation speed.

In the charge mode, the phase voltage of the U-phase, the selected phase voltage signal Vm, converges to 0 V by turning on the switching elements Q2, Q4, and Q6 at all low-sides. The neutral point voltage Vn also converges to 0 V by turning on all the low-side switching elements Q2, Q4, and Q6. The differential voltage detection signal Vd′ also converges to 0 V by turning on all the low-side switching elements Q2, Q4, and Q6. At this time, the differential voltage detection signal Vd becomes Vdc/2 by the differential amplifier circuit 153.

Next, in the discharge mode, the inverter circuit 2a is again set to the first switch state by the idling control signal Id. Specifically, due to the idling control signal Id generated by the first switching unit 21a, all the drive signals input to the gates of the switching elements Q1 to Q6 constituting the inverter circuit 2a are again set to low, and all the switches of the inverter circuit are turned off.

In this state, when the rotor of the motor 3 is idling, the currents circulating between the coils of the motor 3 and the inverter circuit 2a during the charge mode attempts to continue flowing through the coils, so that the inductive kickback occurs because all the switching elements Q1 to Q6 are turned off.

In the discharge mode, due to the occurrence of the inductive kickback, the phase voltage of the U-phase, the selected phase voltage signal Vm, falls in voltage when the selected phase is the most upstream phase of the induced current, rises in voltage when the selected phase is the most downstream phase of the induced current, and rises or falls in voltage when the selected phase is the remaining phase, depending on the direction of the induced current. The induced voltage is clamped by the parasitic diode, and the voltage fluctuation time of the phase at the most downstream side and the phase at the most upstream side of the induced current is the longest. The neutral point voltage Vn changes gradually because the voltage fluctuations due to the different inductive kickback for each phase are synthesized. Thereafter, the influence of the inductive kickback is eliminated, the phase voltage of the U-phase, the selected phase voltage signal Vm, and the neutral point voltage Vn converge to Vin/2, and the coils of the motor and the inverter circuit do not form a closed circuit due to the discharge mode. Thus, the influence of the induced voltage due to the idling of the motor appears from a junction point A of the selected phase voltage signal Vm and a junction point B of the neutral point voltage Vn, and the selected phase voltage signal Vm, the neutral point voltage Vn, and the differential voltage detection signal Vd′ oscillate with a waveform similar to the waveform of the free mode (1).

In the discharge mode, when the phase voltage of the U-phase, the selected phase voltage signal Vm, rises in voltage, the differential voltage detection signal Vd′ becomes the positive side (plus side), and together with the influence of the inductive kickback being eliminated, the oscillation of the sine wave by the induced voltage starts from the descending waveform converging to 0 V. When the phase voltage of the U-phase, the selected phase voltage signal Vm, falls in voltage, the differential voltage detection signal Vd′ becomes the negative side (minus side), and together with the influence of the inductive kickback being eliminated, the oscillation of the sine wave by the induced voltage starts from the ascending waveform converging to 0 V. The differential voltage detection signal Vd′ gradually changes due to the voltage fluctuation different from each phase, and the waveform pattern becomes six types (positive two steps high to low, positive single step, positive two steps low to high, negative two steps high to low, negative single step, and negative two steps low to high). At this time, the differential voltage detection signal Vd becomes a signal almost similar to the differential voltage detection signal Vd′, and the signal is saturated in the voltage range from 0 V to Vdc centered at Vdc/2, by the differential amplifier circuit 153.

Here, the waveform pattern of the differential voltage detection signal Vd′ generated in the discharge mode when the rotor of the motor 3 is idling will be described.

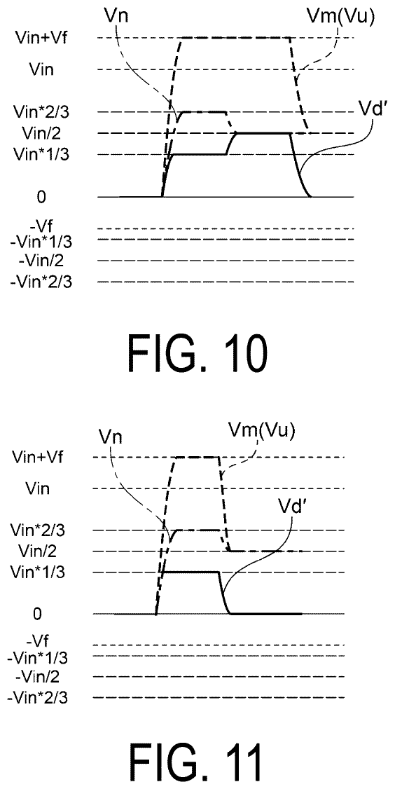

FIGS. 10 to 15 are waveforms illustrating phase voltage patterns and resulting differential voltage patterns generated at the phase voltage detection circuit by inductive kickback in the discharge mode when the rotor of the motor 3 is idling. These signals have voltage fluctuation in the following 6 patterns depending on the position of the rotor of the motor 3. In FIGS. 10 to 15, only the phase voltage of the U-phase as the selected phase voltage signal Vm, the neutral point voltage Vn, and the differential voltage detection signal Vd′ are represented, and the influence of the induced voltage due to the idling of the motor is omitted for simplicity.

When the rotor of the motor 3 is stopped (not idling), the phase voltage of each phase does not change from 0 V regardless of the position of the rotor of the motor 3 because the voltage fluctuation due to the inductive kickback does not occur in the discharge mode. Thus, the phase voltage of the U-phase as the selected phase voltage signal Vm, and the neutral point voltage Vn are both 0 V, and the differential voltage detection signal Vd′ is also 0 V.

FIG. 10 is a diagram illustrating a waveform pattern of a first pattern. In this pattern, the U-phase is the most downstream side of the induced current, the V-phase is the most upstream side of the induced current, and the W-phase is the downstream side of the induced current. At this time, the V-phase and the W-phase may be interchanged.

In this pattern, in the first half, the phase voltage Vu of the U-phase as the selected phase voltage signal Vm, rises due to the DC power supply Vin and the forward voltage Vf of the parasitic diode to Vin+Vf, the phase voltage Vv of the V-phase falls to −Vf, and a phase voltage Vw of the W-phase rises to Vin+Vf. In addition, the neutral point voltage Vn as the combined voltage of these voltages, converges to approximately Vin*⅔ (in the present specification, “*” represents multiplication). As a result, the differential voltage detection signal Vd′ converges to approximately Vin/3.

In the second half, the voltage fluctuations of the phase voltage Vu of the U-phase and the phase voltage Vv of the V-phase are maintained, but the phase voltage Vw of the W-phase with a short voltage fluctuation time decreases to approximately Vin/2. In addition, the neutral point voltage Vn as the combined voltage of these voltages, converges to approximately Vin/2. As a result, the differential voltage detection signal Vd′ converges to approximately Vin/2. Subsequently, the influence of the inductive kickback is eliminated, and the differential voltage detection signal Vd′ converges to approximately 0 V.

As described above, in the first pattern, the differential voltage detection signal Vd′ has a waveform pattern taking two positive values low and high, i.e., a waveform changing from a positive low voltage to a positive high voltage.

FIG. 11 is a diagram illustrating a waveform pattern of a second pattern. In this pattern, the U-phase is the downstream side of the induced current, the V-phase is the most upstream side of the induced current, and the W-phase is the most downstream side of the induced current. At this time, the V-phase and the W-phase may be interchanged.

In this pattern, in the first half, the phase voltage Vu of the U-phase as the selected phase voltage signal Vm, rises to Vin+Vf, the phase voltage Vv of the V-phase falls to −Vf, and the phase voltage Vw of the W-phase rises to Vin+Vf. In addition, the neutral point voltage Vn as the combined voltage of these voltages, converges to approximately Vin*⅔. As a result, the differential voltage detection signal Vd′ converges to approximately Vin/3.

In the latter half, the voltage fluctuations of the phase voltage Vv of the V-phase and the phase voltage Vw of the W-phase are maintained, but the phase voltage Vu of the U-phase with a short voltage fluctuation time, drops to approximately Vin/2. In addition, the neutral point voltage Vn as the combined voltage of these voltages, converges to approximately Vin/2. As a result, the differential voltage detection signal Vd′ converges to approximately 0 V.

Thus, in the second pattern, the differential voltage detection signal Vd′ has a waveform pattern of one positive stage, that is, a waveform taking one positive value.

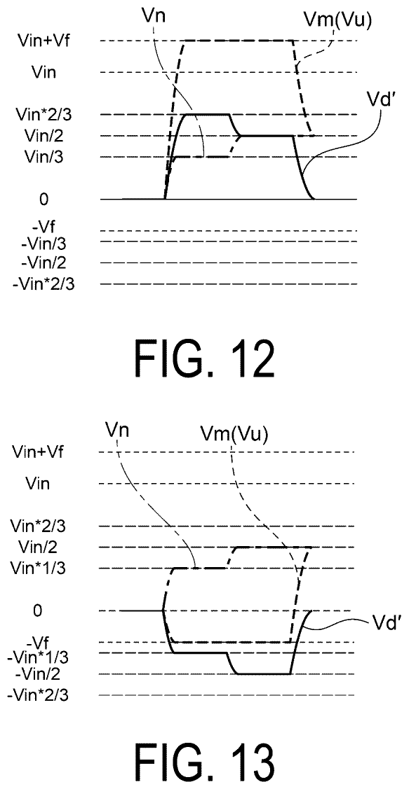

FIG. 12 is a diagram illustrating a waveform pattern of the third pattern. In this pattern, the U-phase is the most downstream side of the induced current, the V-phase is the most upstream side of the induced current, and the W-phase is the upstream side of the induced current. At this time, the V-phase and the W-phase may be interchanged.

In this pattern, in the first half, the phase voltage Vu of the U-phase as the selected phase voltage signal Vm, rises to Vin+Vf, the phase voltage Vv of the V-phase falls to −Vf, and the phase voltage Vw of the W-phase falls to −Vf. In addition, the neutral point voltage Vn as the combined voltage of these voltages, converges to approximately Vin/3. As a result, the differential voltage detection signal Vd′ converges to approximately Vin*⅔.

In the second half, the voltage fluctuations of the phase voltage Vu of the U-phase and the phase voltage Vv of the V-phase are maintained, but the phase voltage Vw of the W-phase with a short voltage fluctuation time rises to approximately Vin/2. In addition, the neutral point voltage Vn as the combined voltage of these voltages, converges to approximately Vin/2. As a result, the differential voltage detection signal Vd′ converges to approximately Vin/2. Subsequently, the influence of the inductive kickback is eliminated, and the differential voltage detection signal Vd′ converges to approximately 0 V.

As described above, in the third pattern, the differential voltage detection signal Vd′ has a waveform pattern taking two positive values high and low, i.e., a waveform changing from a positive high voltage to a positive low voltage.

FIG. 13 is a diagram illustrating a waveform pattern of the fourth pattern. In this pattern, the U-phase is the most upstream side of the induced current, the V-phase is the upstream side of the induced current, and the W-phase is the most downstream side of the induced current. At this time, the V-phase and the W-phase may be interchanged.

In this pattern, in the first half, the phase voltage Vu of the U-phase as the selected phase voltage signal Vm falls to −Vf, the phase voltage Vv of the V-phase falls to −Vf, and the phase voltage Vw of the W-phase rises to Vin+Vf. In addition, the neutral point voltage Vn as the combined voltage of these voltages, converges to approximately Vin/3. As a result, the differential voltage detection signal Vd′ converges to approximately −Vin/3.

In the second half, the voltage fluctuations of the phase voltage Vu of the U-phase and the phase voltage Vw of the W-phase are maintained, but the phase voltage Vv of the V-phase with a short voltage fluctuation time rises to approximately Vin/2. In addition, the neutral point voltage Vn as the combined voltage of these voltages, converges to approximately Vin/2. As a result, the differential voltage detection signal Vd′ converges to approximately −Vin/2. Subsequently, the influence of the inductive kickback is eliminated, and the differential voltage detection signal Vd′ converges to approximately 0 V.

As described above, in the fourth pattern, the differential voltage detection signal Vd′ has a waveform pattern taking two negative values low and high, i.e., a waveform changing from a negative low voltage to a negative high voltage.

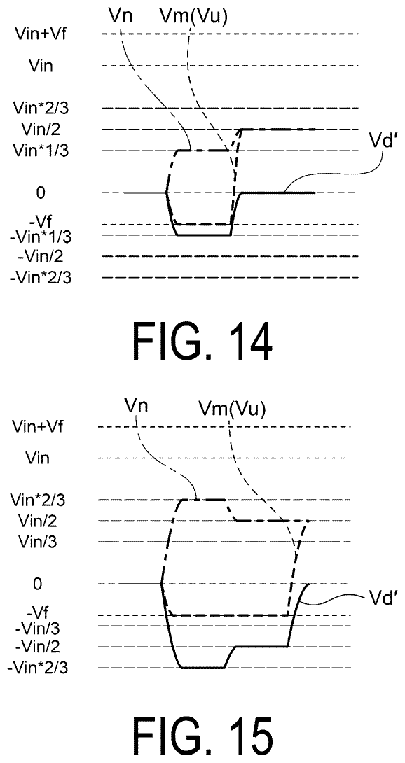

FIG. 14 is a diagram illustrating a waveform pattern of a fifth pattern. In this pattern, the U-phase is at the upstream side of the induced current, the V-phase is at the most upstream side of the induced current, and the W-phase is at the most downstream side of the induced current. At this time, the V-phase and the W-phase may be interchanged.

In this pattern, in the first half, the phase voltage Vu of the U-phase as the selected phase voltage signal Vm falls to −Vf, the phase voltage Vv of the V-phase falls to −Vf, and the phase voltage Vw of the W-phase rises to Vin+Vf. In addition, the neutral point voltage Vn as the combined voltage of these voltages, converges to approximately Vin/3. As a result, the differential voltage detection signal Vd′ converges to approximately −Vin/3.

In the latter half, the voltage fluctuations of the phase voltage Vv of the V-phase and the phase voltage Vw of the W-phase are maintained, but the phase voltage Vu of the U-phase with a short voltage fluctuation time, rises to approximately Vin/2. In addition, the neutral point voltage Vn as the combined voltage of these voltages, converges to approximately Vin/2. As a result, the differential voltage detection signal Vd′ converges to approximately 0 V.

Thus, in the fifth pattern, the differential voltage detection signal Vd′ has a waveform pattern of one negative stage, that is, a waveform pattern taking one negative value.

FIG. 15 is a diagram illustrating a waveform pattern of a sixth pattern. In this pattern, the U-phase is at the most upstream side of the induced current, the V-phase is at the downstream side of the induced current, and the W-phase is at the most downstream side of the induced current. At this time, the V-phase and the W-phase may be interchanged.

In this pattern, in the first half, the phase voltage Vu of the U-phase as the selected phase voltage signal Vm falls to −Vf, the phase voltage Vv of the V-phase rises to Vin+Vf, and the phase voltage Vw of the W-phase rises to Vin+Vf. In addition, the neutral point voltage Vn as the combined voltage of these voltages, converges to approximately Vin*⅔. As a result, the differential voltage detection signal Vd′ converges to approximately −Vin*⅔.

In the second half, the voltage fluctuations of the phase voltage Vu of the U-phase and the phase voltage Vw of the W-phase are maintained, but the phase voltage Vv of the V-phase with a short voltage fluctuation time falls to approximately Vin/2. In addition, the neutral point voltage Vn as the combined voltage of these voltages, converges to approximately Vin/2. As a result, the differential voltage detection signal Vd′ converges to approximately Vin/2. Subsequently, the influence of the inductive kickback is eliminated, and the differential voltage detection signal Vd′ converges to approximately 0 V.

As described above, in the sixth pattern, the differential voltage detection signal Vd′ has a waveform pattern taking two negative values high and low, i.e., a waveform changing from a negative high voltage to a negative low voltage.

From FIGS. 10 to 15, using at least one phase voltage and neutral point voltage allows for detecting whether a motor is idling based on a voltage fluctuation. At this time, the phase voltage may be near 0 V, but by using the phase voltage and neutral point voltage simultaneously, a voltage fluctuation of ±Vin/3 or more can be confirmed, and whether a motor is idling can be detected stably. By directly measuring the phase voltage and the neutral point voltage without using a differential voltage detection circuit, thereby allowing to determine idling by a threshold value. However, by generating a differential voltage for the phase voltage and the neutral point voltage by using a differential amplifier circuit and shifting the differential voltage, thereby allowing to treat the voltage fluctuation as a positive voltage and facilitating idling determination by a threshold value.

Returning to FIG. 9, after the discharge mode, the free mode comes back again. In the free mode after the discharge mode, the inverter circuit 2a is set to the first switch state by the idling control signal Id. Specifically, in response to the idling control signal Id generated by the first switching unit 21a, all the drive signals input to the gates of switching elements Q1 to Q6 constituting the inverter circuit 2a are set to low, and all switches of the inverter circuit are turned off. In this state, the closed circuit is not formed, so that the winding current of the selected phase is 0 A, and no current flows.

In the free mode again, by turning off all switching elements Q1 to Q6, the phase voltage of the U-phase as the selected phase voltage signal Vm, oscillates with a positive side saddle wave having an amplitude, due to the induced voltage and the clamp of the parasitic diode according to the idle rotation speed, and a period according to the idle rotation speed, while the voltage fluctuation due to the inductive kickback converges. By turning off all switching elements Q1 to Q6, the neutral point voltage Vn oscillates with a positive side saddle wave having an amplitude, due to the induced voltage according to the idling rotation speed and the clamp of the parasitic diode, and a period three times of the phase voltage, while the voltage fluctuation due to the inductive kickback converges. By turning off all the switching elements Q1 to Q6, the differential voltage detection signal Vd′ oscillates with a sine wave having an amplitude, due to the induced voltage according to the idling rotation speed, and a period according to the idling rotation speed.

The idling determination unit 22 receives the voltage measurement value Vmeas corresponding to the differential voltage detection signal Vd described above from the voltage measurement unit 17. As described above, the differential voltage detection signal Vd varies variously even in the discharge mode, so that the idling determination unit 22 measures the differential voltage detection signal Vd a plurality of times during the discharge mode, and performs idling determination on the basis of the differential voltage detection signal Vd when the voltage fluctuation is the largest, more than the voltage in the charge mode.

The idling determination unit 22 repeats the measurement of the differential voltage detection signal Vd a plurality of times at a predetermined interval during a predetermined discharge time from after a predetermined mask time. The measurement of the differential voltage detection signal Vd is preferably performed a plurality of times rather than once, because the voltage fluctuation due to the inductive kickback caused by the idling of the motor changes stepwise. For example, the differential voltage detection signal Vd measured in advance in the charge mode is used as the reference voltage, and the idling determination can be performed by calculating the maximum fluctuation voltage difference as the difference between the reference voltage and the measured voltage being the maximum, among the plurality of measured voltages measured in the discharge mode, and comparing the calculated maximum fluctuation voltage difference with a preset idling threshold. The idling determination unit 22 can determine idling of the motor 3 when the maximum fluctuation voltage difference exceeds the predetermined idling threshold. The idling threshold may be a value such that the maximum fluctuation voltage difference, as the difference between the reference voltage of the differential voltage detection signal Vd and the measured voltage becoming the maximum, can be determined at the minimum idling rotation speed to be detected. The differential amplifier circuit 153 may adjust the amplification (reduction) rate of the differential voltage detection signal Vd′ within the range with the idling threshold able to be determined.

Next, the flow of each process in idling detection by the control circuit 1 of the motor drive control device 10 according to an embodiment will be described.

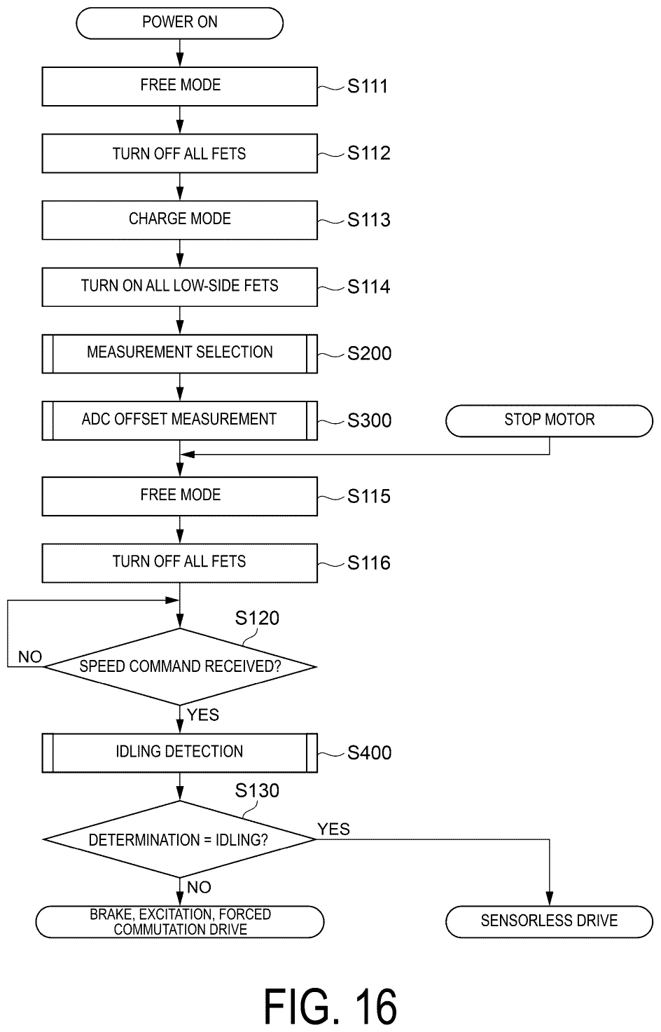

FIG. 16 is a flowchart illustrating an example of the process flow at the time of power-on at the control circuit 1 of the motor drive control device 10 according to an embodiment.

First, when the power is turned on at the motor drive control device 10, as illustrated in FIG. 16, once the state control unit 12 decides to switch to the free mode (step S111), the first switching unit 21a generates the idling control signal Id switching the switching elements Q1 to Q6 constituting the inverter circuit 2a to the first switch state (all the switching elements Q1 to Q6 off) in order to switch the switching elements Q1 to Q6 corresponding to the free mode (step S112).

The state control unit 12 generates the idling control signal Id switching the switching elements Q1 to Q6 constituting the inverter circuit 2a to the first switch state according to the idling control signal Id generated in step S112. According to the idling control signal Id, the switching elements Q1 to Q6 constituting the inverter circuit 2a enter the first switch state illustrated in FIG. 2.

Next, when the state control unit 12 decides to switch to the charge mode (step S113), the second switching unit 21b generates the idling control signal Id switching the switching elements Q1 to Q6 constituting the inverter circuit 2a to the second switch state (with all the low-side switching elements Q2, Q4, Q6 on) in order to perform ADC offset measurement of any one selected phase to detect idling (step S114).

The state control unit 12 generates the idling control signal Id switching the switching elements Q1 to Q6 constituting the inverter circuit 2a to the second switch state according to the idling control signal Id generated in step S114. In response to the idling control signal Id, the switching elements Q1 to Q6 constituting the inverter circuit 2a enter the second switch state with the phase voltage not occurring, as illustrated in FIG. 3.

The control circuit 1 executes measurement selection after step S114 (step S200). For example, when idling detection is performed using phase voltage Vu of the U-phase, the selected phase voltage signal Vm is selected for measurement type selection signal Ss, and the phase voltage Vu of the U-phase is selected for measurement phase selection signal Sm.

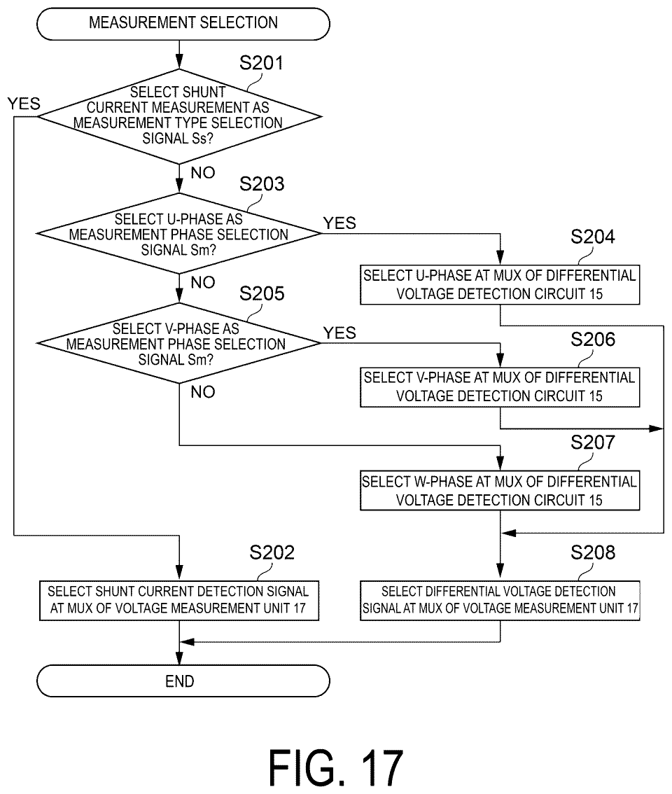

FIG. 17 is a flowchart illustrating an example of the flow of measurement selection by measurement type selection signal Ss and measurement phase selection signal Sm output from state control unit 12 or rectangular wave control unit 13.

When the measurement selection is started, as illustrated in FIG. 17, it is first determined whether the measurement type selection signal Ss selects the shunt current measurement at the voltage measurement unit 17 (step S201). Note that the measurement type selection signal Ss selects the shunt current detection signal Vs for overcurrent detection in the motor drive.

When the measurement type selection signal Ss selects the shunt current measurement (step S201: YES), the measurement type selection multiplexer 171 of the voltage measurement unit 17 selects the shunt current detection signal Vs as the input to the sampling circuit 172 (step S202) and ends the measurement selection.

When the measurement type selection signal Ss does not select the shunt current measurement (step S201: NO), the differential voltage detection circuit 15 determines whether the measurement phase selection signal Sm selects the U-phase (step S203).

When the measurement phase selection signal Sm selects the U-phase (step S203: YES), the measurement phase selection multiplexer 152 of the differential voltage detection circuit 15 selects the phase voltage Vu of the U-phase as the selected phase voltage signal Vm (step S204).

When the measurement phase selection signal Sm does not select the U-phase (step S203: NO), the differential voltage detection circuit 15 determines whether the measurement phase selection signal Sm selects the V-phase (step S205).

When the measurement phase selection signal Sm selects the V-phase (step S205: YES), the measurement phase selection multiplexer 152 of the differential voltage detection circuit 15 selects the phase voltage Vv of the V-phase as the selected phase voltage signal Vm (step S206).

When the measurement phase selection signal Sm does not select the V-phase (step S205: NO), the measurement phase selection multiplexer 152 of the differential voltage detection circuit 15 selects the phase voltage Vw of the W-phase as the selected phase voltage signal Vm (step S207).

After steps S204, S206, and S207, the measurement type selection multiplexer 171 of the voltage measurement unit 17 selects the differential voltage detection signal Vd as the input to the sampling circuit 172 (step S208) and ends the measurement selection.

Referring back to FIG. 16, the control circuit 1 executes ADC offset measurement after step S200 (step S300).

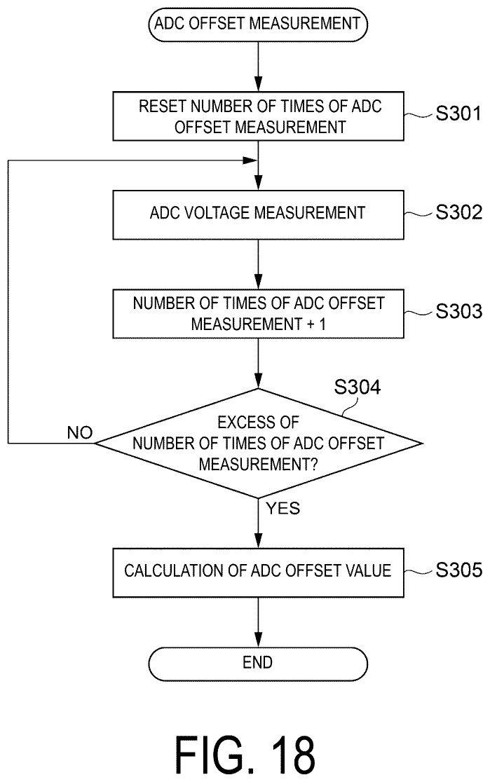

FIG. 18 is a flowchart illustrating an example of the flow of ADC offset measurement by the control circuit 1 of the motor drive control device 10. By executing ADC offset measurement, the ADC offset adjustment value can be obtained. The obtained ADC offset adjustment value can be used by the offset calculator 175.

When the ADC offset measurement is started at the voltage measurement unit 17, as illustrated in FIG. 18, the counter of the number of times of ADC offset measurement is cleared, the ADC offset adjustment value is reset to zero, and the offset calculator 175 is invalidated (step S301).

Next, the voltage measurement unit 17, by switching the sampling circuit 172, performs an A/D conversion on the differential voltage detection signal Vd output from the differential voltage detection circuit 15 selected by the measurement type selection multiplexer 171 of the voltage measurement unit 17, or on the shunt current detection signal Vs output from the current detection circuit 2c, and performs ADC voltage measurement (ADC voltage measurement: step S302). Although the differential voltage detection signal Vd or shunt current detection signal Vs at this time corresponds to 0, the voltage value to be measured may become a value other than zero due to a shift or bias voltage.

At the voltage measurement unit 17, when the ADC voltage measurement in step S302 is completed, the counter of the number of times of ADC offset measurement is incremented by “+1” (step S303).

At the voltage measurement unit 17, the counter of the number of times of ADC offset measurement is checked to determine whether the current number of times of ADC offset measurement exceeds a predetermined number of times of ADC offset measurement (step S304).

When the current number of times of ADC offset measurement does not exceed the predetermined number of times of ADC offset measurement (step S304: NO), the process returns to step S302. On the other hand, when the current number of times of ADC offset measurement exceeds the predetermined number of times of ADC offset measurement (step S304: YES), the average value of the values acquired in the measurement of step S302 is acquired as the ADC offset adjustment value, and the offset calculator 175 is enabled (step S305).

According to the measurement selection in step S200 and the ADC offset measurement in step S300, for example, when idling detection is performed using the phase voltage Vu of the U-phase, the offset adjustment of the differential voltage detection signal Vd is executed. Here, the offset adjustment of the differential voltage detection signal Vd when idling detection is performed using the phase voltage of the V-phase or the W-phase, and the offset adjustment when the shunt current detection signal Vs is selected by the measurement type selection signal Ss, may be performed independently. The average value of the ADC offset adjustment value of each phase voltage may be used as the offset adjustment value of the phase voltage.

Referring back to FIG. 16, when the state control unit 12 decides to switch to the free mode again (step S115), upon completion of the ADC offset measurement, the first switching unit 21a generates the idling control signal Id switching to the first switch state (with all the switching elements Q1 to Q6 off) in order to switch the switching elements Q1 to Q6 constituting the inverter circuit 2a to a switch state corresponding to the free mode again (step S116).

The state control unit 12 generates the idling control signal Id switching the switching elements Q1 to Q6 constituting the inverter circuit 2a to the first switch state according to the idling control signal Id generated in step S116. According to the idling control signal Id, the switching elements Q1 to Q6 constituting the inverter circuit 2a enters the first switch state as illustrated in FIG. 2.

After that, the state control unit 12 determines whether the speed command signal Sc has been received at the drive command acquisition unit 11 in order to wait for starting drive of the motor after turning on the power or stopping the motor (step S120). The state control unit 12 repeats the determination until the speed command signal Sc is received at the drive command acquisition unit 11. In the case of motor stop, before step S120 similar to when the power is turned on, the mode is shifted to the free mode (step S115). For example, when idling detection is performed using the phase voltage Vu of the U-phase, the selected phase voltage signal Vm may be selected for the measurement type selection signal Ss and the phase voltage Vu of the U-phase may be selected for the measurement phase selection signal Sm.

The state control unit 12 executes idling detection in order to detect whether the motor is in idling state immediately before driving the motor when the drive command acquisition unit 11 receives the speed command signal Sc from the host device (step S120: YES) (step S400).

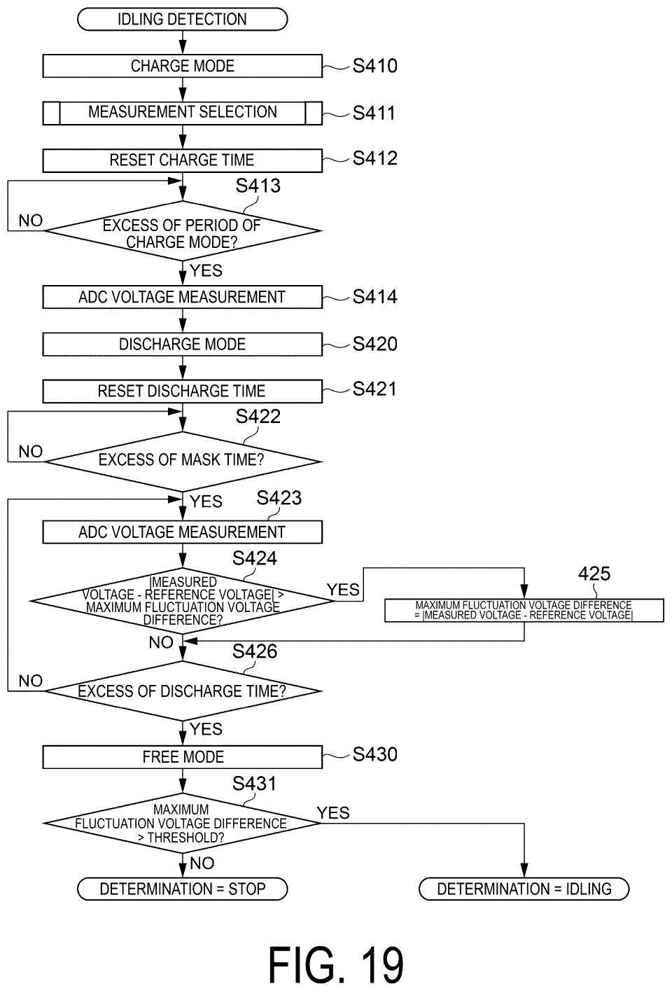

FIG. 19 is a flowchart illustrating an example of the flow of idling detection by the control circuit 1 of the motor drive control device 10. An example of idling detection using the phase voltage Vu of the U-phase will be described here.

When the idling detection in step S400 is started, the switch state is already the first switch state corresponding to the free mode, so that, to shift to the charge mode, the second switching unit 21b at the state control unit 12 first generates the idling control signal Id to switch to the second switch state corresponding to the charge mode, as illustrated in FIG. 19 (step S410).

When the state enters the charge mode, the measurement selection in FIG. 17 is executed to select the phase to be measured (step S411). In this example, the phase voltage Vu of the U-phase is used to perform idling detection, so that the state control unit 12 selects the differential voltage detection signal Vd as the measurement type selection signal Ss and the phase voltage Vu of the U-phase as the measurement phase selection signal Sm. In FIG. 16, a measurement selection S200 is executed before an ADC offset measurement S300, but the measurement selection of FIG. 17 can be executed again at this timing in order to reset the settings of the selected measurement phase selection multiplexer 152 and the measurement type selection multiplexer 171 in driving the motor.

After the phase to be measured is selected in step S411, the charge time is reset at the state control unit 12 (step S412).

According to the idling control signal Id generated in step S410, the state control unit 12 generates the idling control signal Id switching the switching elements Q1 to Q6 constituting the inverter circuit 2a to the second switch state. According to the idling control signal Id, the switching elements Q1 to Q6 constituting the inverter circuit 2a enters the second switch state as illustrated in FIG. 3, for example.

At the state control unit 12, the second switching unit 21b determines whether a predetermined charge time has elapsed since the idling control signal Id is generated in step S410 (step S413).

In the state control unit 12, when a predetermined charge time elapses after the idling control signal Id is generated (step S413: Yes), in order to cause the voltage measurement unit 17 to measure the voltage measurement value Vmeas in a state with the phase voltage not occurring, the second switching unit 21b generates the measurement trigger signal Tr (step S414) in order to cause the voltage measurement unit 17 to measure the voltage measurement value Vmeas, and causes the voltage measurement unit 17 to measure the voltage measurement value Vmeas (ADC voltage measurement). The idling determination unit 22 sets the voltage measurement value Vmeas obtained in step S414 as a reference voltage.

Since the state control unit 12 subsequently shifts to the discharge mode, at the state control unit 12, the first switching unit 21a generates the idling control signal Id switching to the first switch state corresponding to the discharge mode (step S420). At this time, the discharge time and the mask time are reset at the state control unit 12 (step S421).

The state control unit 12 generates the idling control signal Id in step S420 to switch the switching elements Q1 to Q6 constituting the inverter circuit 2a to the first switch state. That is, in response to the idling control signal Id, the switching elements Q1 to Q6 constituting the inverter circuit 2a enters again the first switch state as illustrated in FIG. 4, for example. At this time, when the motor is idling, an inductive kickback occurs at the inverter circuit.

The state control unit 12 determines whether the mask time has elapsed (step S422). When the mask time has elapsed (step S422: Yes), the state control unit 12 generates the measurement trigger signal Tr in order to cause the voltage measurement unit 17 to measure the voltage measurement value Vmeas because voltage fluctuation due to inductive kickback occurs when the motor is idling, and causes the voltage measurement unit 17 to measure the voltage measurement value Vmeas (ADC voltage measurement) (step S423). The idling determination unit 22 sets the voltage measurement value Vmeas obtained in step S423 as the measured voltage.

In the ADC voltage measurement of step S413 and step S423, the state control unit 12 outputs the measurement trigger signal Tr for idling detection to the voltage measurement unit 17 and switches the sampling circuit 172 of the voltage measurement unit 17. For example, when idling detection is performed using the phase voltage Vu of the U-phase, the voltage measurement unit 17 performs A/D conversion for the differential voltage detection signal Vd corresponding to the phase voltage Vu of the U-phase output from the differential voltage detection circuit 15 and further performs ADC offset adjustment to generate the voltage measurement value Vmeas. The voltage measurement unit 17 outputs the voltage measurement value Vmeas to the idling determination unit 22 of the state control unit 12. Therefore, the voltage measurement value Vmeas corresponds to the voltage obtained by adjusting the ADC offset of the difference voltage (differential voltage detection signal Vd) between the phase voltage of the selected phase (selected phase voltage signal Vm) and the neutral point voltage (neutral point voltage Vn) by the ADC offset adjustment value.

At the state control unit 12, the idling determination unit 22 determines whether the difference (differential voltage detection signal Vd) between the reference voltage obtained in step S414 and the measured voltage obtained in step S423 is greater than the maximum fluctuation voltage difference (step S424). In the determination in step S424, when the difference between the reference voltage and the measured voltage is greater than the maximum fluctuation voltage difference (step S424: Yes), the maximum fluctuation voltage difference is updated to the value of the current difference (step S425). In step S425, the difference between the reference voltage obtained in step S414 and the measured voltage obtained in step S423 is taken as the maximum fluctuation voltage difference, and is subsequently updated.

The state control unit 12 determines whether the discharge time has elapsed (step S426). When the discharge time has elapsed (step S426: Yes), the state control unit 12 enters the free mode (step S430). On the other hand, when the discharge time has not elapsed (step S426: No), the state control unit 12 again performs ADC voltage measurement (steps S423 to S425). As illustrated in FIG. 9, after the mask time of step S422 elapses, the state control unit 12 generates a discharge measurement trigger signal Tr at a predetermined period until the discharge time elapses, and causes the voltage measurement unit 17 to measure a plurality of voltage measurement values Vmeas (steps S423 to S426).

The idling determination unit 22 determines whether the motor 3 is idling based on the maximum fluctuation voltage difference generated in steps S423 to S426 (step S431). The idling determination unit 22 compares the maximum fluctuation voltage difference with the idling threshold in step S431 to determine whether the motor 3 is idling.

The idling determination unit 22 determines idling of the motor 3 when the maximum fluctuation voltage difference exceeds the threshold (step S431: YES).

On the other hand, the idling determination unit 22 determines a stop state (not idling) of the motor 3 when the maximum fluctuation voltage difference does not exceed the threshold (step S431: No). The idling determination unit 22 generates an idling determination signal indicating the idling determination result. The idling determination signal is used by the state control unit 12.

Referring back to FIG. 16, the state control unit 12 determines from the generated idling determination signal whether the motor 3 is determined to be idling (step S130), and when determined to be idling (step S130: YES), the motor is driven by sensorless drive. On the other hand, when determined to be not idling by the state control unit 12 (step S130: NO), the drive of the motor by braking, excitation, and forced commutation start, or the like is executed.

The control circuit 1 of the motor drive control device 10, when the rotor of the motor 3 is idling, generates induced currents circulating between the coils of the motor 3 and the inverter circuit 2a by switching each of the switch states of the switching elements Q1 to Q6 of the inverter circuit 2a. Thereafter, the control circuit 1 determines idling of the motor 3 based on the phase voltages generated by the inductive kickback generated at the inverter circuit when the paths of the induced currents are interrupted.

Thus, the motor drive control device 10 can stably detect whether the motor 3 is idling in a short time without using a position sensor.

At the motor drive control device 10 according to the above embodiment, the control circuit 1 includes: the first switching unit 21a configured to switch from a first switch state with all of the high side switches and the low side switches included in the inverter circuit 2a turned off to a second switch state with all of either the high side switches or the low side switches included in the inverter circuit 2a turned on; the second switching unit 21b configured to switch from the second switch state to the first switch state; and the idling determination unit 22 configured to determine idling of the motor based on the phase voltage generated at the phase voltage detection circuit when switching from the second switch state to the first switch state.

This enables each of the switching elements Q1 to Q6 of the inverter circuit 2a to switch to the respective switch states corresponding to the three modes (free mode, charge mode, discharge mode) for detecting the idling of the motor 3, thereby allowing detection whether the motor 3 is idling.

At the motor drive control device 10 according to the above embodiment, the control circuit 1 includes the differential voltage detection circuit 15 detecting as the differential voltage detection signal Vd the differential voltage between the phase voltage of one selected phase at the phase voltage detection circuit and the neutral point voltage Vn obtained by synthesizing the phase voltages of all phases at the phase voltage detection circuit. The idling determination unit 22 determines whether the motor 3 is idling based on the differential voltage detection signal Vd.

This allows to determine the idling of the motor 3, by using the neutral point voltage Vn synthesized from the phase voltages, based on the differential voltage between the phase voltage of one selected phase and the neutral point voltage Vn obtained by synthesizing the phase voltages of all phases.

At the motor drive control device 10 according to the above embodiment, the idling determination unit 22 uses as the reference voltage the differential voltage detection signal Vd detected at the differential voltage detection circuit 15 in the second switch state.

Accordingly, the idling determination unit 22 uses the differential voltage detection signal Vd detected at the differential voltage detection circuit 15 as the reference voltage for idling determination because no induced voltage is generated at the phase voltage detection circuit in the second switch state.

When the motor drive control device 10 according to the embodiment switches from the second switch state to the first switch state, the differential voltage detection signals Vd detected at the differential voltage detection circuit 15 for a plurality of times are used as the measured voltages to calculate the maximum fluctuation voltage difference with the difference between the reference voltage and the measured voltage being maximum. Then, when the calculated maximum fluctuation voltage difference is larger than a threshold value, the motor 3 is determined to be idle.

Accordingly, the idling determination can be stably performed in the discharge mode by utilizing voltage fluctuation of the phase voltage by the inductive kickback.

### Expansion of Embodiments

Although the invention made by the present inventors has been specifically described based on the embodiments described above, the present invention is not limited thereto, and obviously various modifications can be made to the extent not deviating from the gist thereof.

In the embodiments, a case with the speed command signal Sc including a target value (target rotation speed) of the rotation speed of the motor 3 has been illustrated, but not limited to this. For example, the speed command signal Sc may be a torque command signal specifying the torque of the motor 3.

In the embodiments, the motor drive control device 10 has been described based on an example with a position sensor not used, but a position sensor may be provided. Even in this case, the position sensor is used for driving the motor and is not required for detecting idling. As the position sensor, a Hall element outputting a Hall signal may be used, or other signals corresponding to the position of the rotor of the motor 3 may be input as rotor position detection signals instead of such Hall signals. For example, an encoder, a resolver or the like may be provided so that the detection signals are input to the control circuit 1. The measurement circuit for each phase voltage may be configured so that the signals of an A/D converter or a comparator comparing each phase voltage with the neutral point voltage are input as the rotor position detection signals.

In the embodiments, the motor drive control device 10 has been described by an example of a configuration to perform overcurrent detection using the current detection circuit 2c, but when overcurrent detection is not performed, the current detection circuit 2c may not be provided. In this case, the measurement type selection multiplexer 171 at the voltage measurement unit 17 may be omitted, and the measurement type selection signal Ss input to the measurement type selection multiplexer 171 may be omitted.

In the embodiments, the control circuit 1 is not limited to the above-described circuit configuration. Various circuit configurations to suit the purposes of the present invention is applied to the control circuit 1.

Specifically, the voltage determination unit 16 may be used instead of the voltage measurement unit 17 to output a threshold (idling threshold) signal from the D/A converter 161 for comparator. When the maximum differential voltage detection signal Vd exceeds this threshold, the motor 3 may be determined to be idling and the idling determination signal may be output to the state control unit 12. In addition, a plurality of comparators and A/D converters may be used instead of the multiplexers of the differential voltage detection circuit 15 and the voltage measurement unit 17.

In the embodiments, the charge mode and the discharge mode may be repeated periodically to detect whether the motor is idling and to wait for the motor to stop.

In the embodiments, the motor drive is not limited to a 120 degree energized square wave drive. A 150 degree energized square wave drive or a sine wave drive may be used.

In the embodiments, the number of phases of the motor 3 driven by the motor drive control device 10 is not limited to three.

The flowcharts described above are specific examples and not limited to these flowcharts. For example, other processes may be inserted between each step or the processes may be parallelized.

In the ADC offset measurement of step S300 in the flowcharts described above, the end of the number of ADC voltage measurements is determined by whether the number of ADC offset measurements in step S304 is exceeded, but instead, whether the measurement time is exceeded may be determined.

In the ADC idling detection of step S400 of the flowchart described above, the end of the number of ADC voltage measurements is determined by whether the discharge time in step S426 is exceeded, but instead, whether the number of measurements is exceeded may be determined.

### REFERENCE SIGNS LIST

1 Control circuit; 2 Drive circuit; 2a Inverter circuit; 2b Pre-drive circuit; 2c Current detection circuit; 3 Motor; 10 Motor drive control device; 11 Drive command acquisition unit; 12 State control unit; 13 Rectangular wave control unit; 14 PWM signal generation unit; 15 Differential voltage detection circuit; 16 Voltage determination unit; 17 Voltage measurement unit; 21a First switching unit; 21b Second switching unit; 22 Idling determination unit; 151 A plurality of resistance elements for limiting DC current and adjusting voltage; 152 Measurement phase selection multiplexer; 153 Differential amplifier circuit; 161 D/A converter for comparator; 162 Comparator; 171 Measurement type selection multiplexer; 172 Sampling circuit; 173 D/A converter for A/D converter; 174 Comparator; 175 Offset calculator; 100 Motor unit; Q1 to Q6 Switching elements; Rs Shunt resistor; Sc Speed command signal; Sd Drive control signal; Id Idling control signal; ωref Target rotation speed; So Drive command signal; Sm Measurement phase selection signal; Ss Measurement type selection signal; Tr Measurement trigger signal; Vjudge Voltage determination signal; Vmeas Voltage measurement value; Vd, Vd′ Differential voltage detection signal; Vm Selected phase voltage signal; Vn Neutral point voltage (Composite signal); Vdc, Vin DC power supply; Vs Shunt current detection signal; Vuu, Vul, Vvu, Vvl, Vwu, Vwl Drive signal; Vu, Vv, Vw Phase voltage; Lu, Lv, Lw Coil; Iu, Iv, Iw Winding current; eu, ev, ew Induced voltage

1. A motor drive control device, comprising:
a control circuit configured to generate a drive control signal for driving a motor including at least one phase of coil;
a drive circuit including an inverter circuit including a high side switch and a low side switch, the high side switch and the low side switch being provided corresponding to each phase of coil of the motor and connected in series with each other, the drive circuit being configured to rotate a rotor of the motor by alternately turning the high side switch and the low side switch on and off in response to the drive control signal to switch an energization direction of the corresponding phase of coil; and
a phase voltage detection circuit configured to detect a phase voltage generated between the inverter circuit and each phase of coil of the motor,
wherein
the control circuit generates an idling control signal instead of the drive control signal and switches a switch state of the inverter circuit to generate an induced current circulating between each phase of coil of the motor and the inverter circuit when the rotor of the motor is idling, and then the control circuit determines idling of the motor based on a phase voltage generated at the phase voltage detection circuit by an inductive kickback generated at the inverter circuit when a path of the induced current is blocked,

2. The motor drive control device according to claim 1, wherein
the control circuit includes:
a first switching unit configured to switch from a first switch state with all of the high side switches and the low side switches included in the inverter circuit being turned off to a second switch state with all of either the high side switches or the low side switches included in the inverter circuit being turned on;
a second switching unit configured to switch from the second switch state to the first switch state; and
an idling determination unit configured to determine idling of the motor based on the phase voltage generated at the phase voltage detection circuit when switching from the second switch state to the first switch state.

3. The motor drive control device according to claim 2, wherein
the control circuit includes a differential voltage detection circuit configured to detect, as a differential voltage detection signal, a differential voltage between the phase voltage of one selected phase at the phase voltage detection circuit and a neutral point voltage obtained by synthesizing the phase voltages of all phases at the phase voltage detection circuit, and
the idling determination unit is configured to determine idling of the motor based on the differential voltage detection signal.

4. The motor drive control device according to claim 3, wherein
the idling determination unit sets the differential voltage detection signal detected at the differential voltage detection circuit in the second switch state to a reference voltage.

5. The motor drive control device according to claim 4, wherein
when the switch state is switched from the second switch state to the first switch state, the differential voltage detection signal detected at the differential voltage detection circuit for a plurality of times is used as a measured voltage to calculate a maximum fluctuation voltage difference with the difference between the reference voltage and the measured voltage being maximum, and then when the calculated maximum fluctuation voltage difference is larger than a threshold value, the motor is determined to be idling.

6. A method for detecting idling of a motor, the method being executed at a motor drive control device, the motor drive control device including:
a control circuit configured to generate a drive control signal for driving a motor including at least one phase of coil;
a drive circuit including an inverter circuit including a high side switch and a low side switch, the high side switch and the low side switch being provided corresponding to each phase of coil of the motor and connected in series with each other, the drive circuit being configured to rotate a rotor of the motor by alternately turning the high side switch and the low side switch on and off in response to the drive control signal to switch an energization direction of the corresponding phase of coil; and
a phase voltage detection circuit configured to detect a phase voltage generated between the inverter circuit and each phase of coil of the motor,
the method comprising:
a first step of switching from a first switch state with all of the high side switches and the low side switches included in the inverter circuit being turned off to a second switch state with all of either the high side switches or the low side switches included in the inverter circuit being turned on;
a second step of switching from the second switch state to the first switch state; and
a third step of determining idling of the motor based on the phase voltage when switching to the first switch state.
